(19) United States
(12) Patent Application Publication
(10) Pub. No.: US 2016/0322524 A1
(43) Pub. Date: Nov. 3, 2016

(54) PHOTOVOLTAIC MODULES AND METHODS OF MAKING THE SAME

(71) Applicant: PPG Industries Ohio, Inc., Cleveland, OH (US)

(72) Inventors: Jiping Shao, Sewickley, PA (US); Brian Woodworth, Pittsburgh, PA (US); Irina G. Schwendeman, Wexford, PA (US)

(21) Appl. No.: 14/698,887

(22) Filed: Apr. 29, 2015

(51) Int. Cl. H01L 31/048; H01L 31/0216; H01L 31/049

(52) U.S. Cl. CPC H01L 31/0481; H01L 31/048; H01L 31/049; H01L 31/02167

(57) ABSTRACT

Photovoltaic modules and methods of making photovoltaic modules are disclosed. The photovoltaic modules comprise a front transparency, a photovoltaic cell, a treated surface of an encapsulating material, and a back coat.

### TECHNICAL FIELD

The present invention relates to photovoltaic modules and, more particularly, methods useful for adhesion of coating compositions for coating or encapsulation of photovoltaic modules.

### BACKGROUND

Photovoltaic modules produce electricity by converting electromagnetic energy into electrical energy. Photovoltaic modules use encapsulant materials to provide durability, weather resistance, and increased service life, particularly in outdoor operating environments.

There are many types of thin film photovoltaic modules that have been developed. While various materials and configurations exist among the thin film technology, most thin film photovoltaic modules comprise the following basic elements: a transparent front layer, which can be glass, transparent polymer, or transparent coating; a transparent, conductive top layer or grid that carries away current; a thin central sandwich of semiconductors that form junctions to separate charge; a back contact that can be a metal film; an encapsulant layer; and a backsheet that protects from the environment and that can provide support to the module if needed. As used herein, the term “layer” refers to a thickness or sheet of material that can be used to cover or coat a surface or body.

A bulk photovoltaic module comprises a front transparency, such as a glass sheet or a pre-formed transparent polymer sheet (for example, a polyimide sheet); an encapsulant such as ethylene vinyl acetate (EVA); photovoltaic cells comprising wafers of photovoltaic semiconducting material such as a crystalline silicon (c-Si); a back encapsulant and a back sheet. Bulk photovoltaic modules are often produced in a batch or semi-batch vacuum lamination process in which the module components are preassembled into a module preassembly. The preassembly process comprises depositing the encapsulant material onto the front transparency, positioning the photovoltaic cells and electrical interconnections onto the encapsulant material, depositing additional encapsulant material onto the photovoltaic cell assembly, and depositing the back sheet onto the back side encapsulant material to complete the module preassembly. The module preassembly is placed in a specialized vacuum lamination apparatus that uses a compliant diaphragm to compress the module assembly and cure the encapsulant material under reduced pressure and elevated temperature conditions to produce the laminated photovoltaic module. The process effectively laminates the photovoltaic cells between the front transparency and a back sheet with the intermediate encapsulant material securing and sealing the photovoltaic cells. A similar lamination process can be used to produce thin film photovoltaic modules, wherein the encapsulant material and the back sheet are laminated to a front transparency comprising deposited photovoltaic thin film layers.

The information described in this background section is not admitted to be prior art.

### SUMMARY

A method for preparing a photovoltaic module comprises depositing an encapsulating material onto at least a portion of a photovoltaic cell, curing the encapsulating material, and treating at least a portion of a surface of the cured encapsulating material. The method further comprises depositing a liquid coating composition onto at least a portion of the treated encapsulating material and curing the liquid coating composition to form a back coat.

A photovoltaic module comprises a front transparency, a photovoltaic cell, an encapsulating material deposited on at least a portion of the photovoltaic cell, a treated surface of at least a portion of the encapsulating material, and a back coat deposited on at least a portion of the treated surface of the encapsulating material.

It is understood that the invention disclosed and described in this specification is not limited to this Summary.

### BRIEF DESCRIPTION OF THE DRAWINGS

Various features and characteristics of the non-limiting and non-exhaustive invention disclosed and described in this specification can be better understood by reference to the accompanying figures, in which:

FIG. 1 is a schematic diagram illustrating an inventive bulk photovoltaic module comprising a protective coating system;

FIG. 2 is a schematic diagram illustrating an inventive thin film photovoltaic module comprising a protective coating system;

FIG. 3 is a schematic diagram illustrating an inventive method of preparing a photovoltaic module comprising a protective coating system; and

FIGS. 4A-4F are photographs of cured silicone encapsulant on glass with a liquid back coat applied; FIG. 4A shows a back side of the coated glass sample A coated with a polyurea resin back coat after cross-hatch adhesion testing before and after 10 days of damp heat exposure; FIG. 4B shows a back side of the coated glass sample B coated with a DOW CORNING® 1200 OS primer and a polyurea resin backcoat after cross-hatch adhesion testing before and after 10 days of damp heat exposure; FIG. 4C shows a back side of the coated glass sample C treated with a corona discharge and a polyurea resin backcoat after cross-hatch adhesion testing before and after 10 days of damp heat exposure; FIG. 4D shows a back side of the coated glass sample D coated with a CORAFLON® fluoropolymer resin back coat after cross-hatch adhesion testing before and after 10 days of damp heat exposure; FIG. 4E shows a back side of the coated glass sample E coated with a DOW CORNING® 1200 OS primer and a CORAFLON® fluoropolymer resin backcoat after cross-hatch adhesion testing before and after 10 days of damp heat exposure; and FIG. 4F shows a back side of the coated glass sample F treated with a corona discharge and a CORAFLON® fluoropolymer resin backcoat after cross-hatch adhesion testing before and after 10 days of damp heat exposure.

The reader will appreciate the foregoing details, as well as others, upon considering the following detailed description of the non-limiting and non-exhaustive invention according to this specification.

### DESCRIPTION

The invention described in this specification relates to protective coating systems that can provide advantages to photovoltaic modules, such as good durability, moisture barrier, abrasion resistance, and the like.

A photovoltaic module is described. The photovoltaic module comprises a front transparency, a photovoltaic cell, an encapsulating material deposited on at least a portion of the photovoltaic cell, a treated surface of at least a portion of the encapsulating material, and a back coat deposited on at least a portion of the treated surface of the encapsulating material. The encapsulating material encapsulates a photovoltaic cell and includes a treated surface. The treated surface of the encapsulating material can comprise a surface of a cured layer formed from a flowable coating composition, wherein at least a portion of the surface can be treated with a corona discharge, a plasma, an ultraviolet ozone, a plume discharge, a brush discharge, a glow discharge, a luminous discharge, or combinations of any thereof.

As used herein the term “front transparency” refers to a material that can be transparent to electromagnetic radiation in a wavelength range that is absorbed by a photovoltaic cell to generate electricity. The front transparency can comprise a planar sheet of transparent material comprising an outward-facing surface of a photovoltaic module. Any suitable transparent material can be used for the front transparency including, but not limited to, glasses such as, for example, silicate glasses, and polymers such as, for example, polyimide, polycarbonate, and the like, or other planar sheet material that can be transparent to electromagnetic radiation in a wavelength range that can be absorbed by a photovoltaic cell and used to generate electricity in a photovoltaic module. As used herein the term “transparent” refers to the property of a material in which at least a portion of incident electromagnetic radiation in the visible spectrum (i.e., approximately 350 to 750 nanometer wavelength) passes through the material with negligible attenuation.

As will be apparent to those skilled in the art and as used herein, the term “photovoltaic cell” refers to a photovoltaic layer that is capable of producing a voltage when exposed to radiant energy. The photovoltaic layer can be comprised of multiple layers. For example, the photovoltaic layer can comprise a midlayer surrounded on each side by other layers. The midlayer, which can itself be comprised of multiple layers, comprises a voltage or electron generating material; that is, a semi-conducting material. The electron generating material can include, for example, amorphous silicon, film crystalline silicon, copper indium diselenide, cadmium telluride (“CdTe”) and/or like materials. This electron generating layer can comprise alternating n-type and p-type semiconductor layers to form a junction, which can be multi junction or single junction. The midlayer can be sandwiched between two other layers, both of which are conductive. A first layer closest to the transparent superstrate can be comprised of a transparent, conductive oxide, for example, indium tin oxide. In addition, there can be a second conductive layer on the opposite side of the midlayer. The second conductive layer can comprise a metallic layer, such as aluminum, that can be deposited through, for example, sputtering. It will be understood that the electron generating material needs to be exposed to radiant energy on at least one side. Thus, the layers that are on one side of the electron generating material should be transparent to such energy. While exemplary photovoltaic layers are described above, any photovoltaic layer can be used according to the invention.

The photovoltaic cells of the invention comprise a transparent superstrate on one side of the photovoltaic layer. The transparent superstrate is transparent to radiant energy, particularly light, since it is this energy that will generate the current in the electron generating layer. Superstrates can include those made from glass or transparent polymers, such as polyimides. Suitable superstrates are commercially available from AFG Industries, Kingsport, Tenn., USA and can be purchased either plain or with a conductive oxide already deposited thereon. While as many layers as desired can be deposited between the superstrate and the electron generating layer, as noted above, such layers should be transparent to permit exposure of the electron generating material to radiant energy. The thin film photovoltaic cells of the present invention further comprise a protective coating as the encapsulant material.

The encapsulating material can comprise a flowable coating composition which can be cured to a clear layer after deposition. As used herein, the term “clear” refers to samples exhibiting a transmittance exceeding 85% as evaluated under ASTM E 308-06 “Standard Practice for Computing the Colors of Objects by Using the Commission Internationale de l'Eclairage (CIE) System” developed by ASTM International, West Conshohocken, Pa., U.S.A. For example, the term “clear” refers to samples of 10 mils thickness film deposited on Solarphire PV glass (3.2 mm glass) exhibiting a transmittance exceeding 85% evaluated using the ASTM E 308-06 standard (employing an X-Rite® Color i® 7 Spectrophotometer, commercially available from X-Rite, Inc., Grand Rapids, Mich., USA) using a CIE system Y value for D65 (incandescent) illumination and a 10° standard observer. As used herein to describe a flowable coating composition to be used as encapsulant the term “flowable” includes liquids, powders and/or other materials that are able to flow into or fill the shape of a space.

As used herein, the term “cured,” as used herein, refers to the condition of a liquid coating composition in which a film or layer formed from the liquid coating composition is at least set-to-touch. As used herein, the terms “cure” and “curing” refer to the progression of a liquid coating composition from the liquid state to a cured state and encompass physical drying of coating compositions through solvent or carrier evaporation (e.g., thermoplastic coating compositions) and/or chemical crosslinking of components in the coating compositions (e.g., thermosetting coating compositions).

As used herein, the terms “treating,” “treated,” “treatment,” or other like terms, refers to alteration, manipulation, or chemical or physical modification of a substrate surface to create a surface that is altered from its original state. For example, treating at least a portion of a surface of the cured encapsulating material can comprise treating at least a portion of the surface of the cured encapsulating material that is opposite to the front transparency with a corona discharge, a plasma, an ultraviolet ozone, a plume discharge, a brush discharge, a glow discharge, a luminous discharge, a texturing process, a primer coating, or the like, or combinations of any thereof.

The treated surface can comprise at least a portion of a surface treated with a corona discharge, plasma, a flame system, an atmospheric plasma, plume discharge, brush discharge, glow discharge, luminous discharge, and/or ultraviolet ozone, or the like, and combinations of any thereof. These surface treatments result in a modification of the encapsulating material's surface energy and bonding ability through the excitation of molecules due to the corona or electrical discharge.

As used herein, the term “corona discharge” and “corona treatment” refers to a surface modification technique that uses a low temperature corona discharge plasma to impart changes in the properties of a surface. The corona plasma is generated by the application of high voltage to sharp electrode tips which form plasma at the ends of the electrode tips. A linear array of electrodes is often used to create a curtain of corona plasma. Materials such as plastics, cloth, or paper can be passed through the corona plasma curtain in order to change the surface energy of the material. The corona discharge can occur when the strength of the electric field around the conductor can be high enough to form a conductive region, but not high enough to cause electrical arcing to nearby objects.

A corona treating system can consist of two major components: a power supply and a treater station. The treater can apply the power to the material surface, through an air gap, via a pair of electrodes, one at high potential and a roll supporting the material at the ground potential. Only the side of the material facing the high potential electrode can be activated to provide an increase in the surface energy. Electrons generated in the corona discharge can impact on the material surface with energies two to three times greater than the energy sufficient to break molecular bonds on the material surface. Free radicals resulting from the corona discharge treatment subsequently react rapidly with oxidizing molecules to form an oxidation layer on the surface of the material. Thus, when the encapsulating material can be treated with a corona discharge, the formed oxides can increase surface energy of the encapsulating material, promote better wetting and can deposit reactive polar groups, such as hydroxyl, carbonyl, and amide groups onto the encapsulating material surface. Surface treatment of the encapsulating material with a corona discharge can be achieved using a hand held corona treater. For example, the surface corona discharge treatment can be achieved using a BD-20AC Laboratory Corona Treater, commercially available from Electro-Technic Products, Chicago, Ill. The BD-20AC Laboratory Corona Treater can be administered at a distance from the instrument to the surface in a range of ⅛ inch (0.32 cm) to 1 inch (2.54 cm) and an input voltage of 115V.

At least a portion of the encapsulating material surface can be treated using a flame system. A flame system creates a flame plasma field when flammable gas and air are combined and combusted to form a blue flame. Brief exposure to particles within the flame can affect the distribution and density of electrons on the encapsulating material surface. Much like corona discharge, the flame system acts to polarize surface molecules through oxidation and deposits other functional chemical groups that further promote surface wetting and adhesion.

“Plasma” functionalization and “plasma discharge” activation as used herein refers to a method of functionalizing a surface by means of plasma processing. Plasma can refer to an ionized gas, or ionized ambient air containing not only ions but also free radicals, electrons and molecular fragments. It is the interaction of these excited species with solid surfaces placed in opposition to the plasma that results in the chemical and physical modification of the material surface. The effect of the plasma on a given material can be determined by the chemistry of the reactions between the surface and the reactive species present in the plasma. At low exposure energies, often used for surface treatment, the plasma surface interactions only change the surface of the material; the effects can be confined to a region only several molecular layers deep and do not change the bulk properties of the substrate. For example, the dissipation of the energy transfers within the solid by a variety of chemical and physical processes can result in a unique type of surface modification that reacts with surfaces in depths from several hundred angstroms to 10 μm without changing the bulk properties of the material.

The surface changes resulting from the plasma treatment depend on the composition of the surface and the gas used. Gases or mixtures of gases, used for plasma treatment of polymers can include nitrogen, argon, oxygen, helium, nitrous oxide, water vapor, halogens, carbon dioxide, methane, ammonia, and the like, and combinations of any thereof. Each gas produces a unique plasma composition and results in different surface properties. For example, the surface energy can be increased very quickly and effectively by plasma-induced oxidation. Depending on the chemistry of the polymer and the source gases, substitution of molecular moieties into the surface can make polymers very wettable.

At least a portion of the encapsulating material surface can be treated using an atmospheric plasma discharge, or atmospheric plasma treatment (APT). Similar to corona discharge, atmospheric plasma discharge can be generated at atmospheric pressure. Instead of using air, this method relies on other gases that deposit specific chemical groups onto the surface of the substrate to improve its surface energy and adhesion characteristics. An atmospheric plasma discharge process acts on the material surface by exposing the polymer surface to a low-temperature high density glow discharge apparatus. This apparatus can comprise a chamber containing spaced-apart electrodes having opposing surfaces. A relatively inert gas such as helium or argon can be fed into the chamber. The electrodes can be energized by a radio frequency power amplifier, microwaves, or alternating or direct current to cause a glow discharge to take place to perform the plasma excitation that results in the surface treatment of the material. Free electrons gain energy from the imposed high frequency electric field (or other energy source) colliding with neutral gas molecules and transferring energy, dissociating the molecules to form numerous reactive species.

A wide variety of parameters can affect the physical characteristics of plasma and subsequently affect the surface chemistry obtained by plasma modification. Processing parameters, such as gas types, treatment power, treatment time and operating pressure, can be varied by the user; however system parameters, such as electrode location, reactor design, gas inlets and vacuum are set by the design of the plasma equipment. This broad range of parameters offers greater control over the plasma process than that offered by many high-energy radiation processes.

As used herein, the term “ultraviolet ozone,” “UV-Ozone,” or “UVO,” refers to the use of ultra violet light and ozone to both clean and modify the molecular surface of solids. Organic anti-adhesion coatings such as, for example, hydrocarbon and fluorocarbon based self-assembled organosilanes and siloxanes can be treated using UVO to improve the adhesion properties. UVO can be used to selectively treat portions of the coating surface by exposing the surface simultaneously to multiple wavelengths of ultraviolet light that excite and dissociate organic molecules from the anti-adhesion coating. The UVO process can generate atomic oxygen from molecular oxygen and ozone so that the organic molecules react with atomic oxygen to form volatile products that can be dissipated, resulting in removal of a layer of the coating surface. UVO can be performed with two wavelengths of ultraviolet light, one at around 184.9 nm and another around 253.7 nm. During the UVO process, organic molecules such as silanes can be excited and dissociated by the adsorption of short-wavelength UV radiation. Atomic oxygen can be simultaneously generated when molecular oxygen is dissociated by the 184.9 nm radiation and ozone is dissociated by the 253.7 nm radiation. The 253.7 nm radiation can be adsorbed by most organics and also by ozone. The organic molecules can react with the atomic oxygen to form volatile products that can be dissipated, resulting in the removal of a layer of the anti-adhesion coating surface

Physical and chemical advantages of the treated surface of the encapsulating material can include a modification of the encapsulating material surface energy and bonding ability through the excitation of molecules due to a corona or electrical discharge. The treated surface of the encapsulating material provides for strength in the adhesion of the back coat to the encapsulating material. As used herein, the term “adhesion” refers to the ability of a first compound to attach to, stick to, or adhere to a second compound or surface.

As discussed above, the cured encapsulating material surface can comprise at least a portion of a surface treated with a corona discharge, a plasma, an ultraviolet ozone, and/or can also be surface treated using deposition of a primer coating. The photovoltaic modules of the invention, as described above, can further include a primer coat. For example, the photovoltaic module can further comprise a primer coat positioned in between the back coat and the cured encapsulating material, or between the back coat and the treated surface of the encapsulating material. As used herein, the terms “primer coat,” “primer coating composition,” “primer,” or like terms refer to coats or coating compositions forming an undercoating deposited onto a substrate over which a topcoat can be deposited. The primer coat can provide for anti-corrosion protection. For example, the primer can comprise silicone and/or octamethyltrisiloxane. The primer coat can comprise any suitable coating compositions such as, for example, DOW CORNING® 1200 OS Primer (a primer for silicone adhesives/sealants) commercially available from Dow Corning Corporation, Midland, Mich., USA, a silicone coating, a siloxane coating, an octamethyltrisiloxane coating, or combinations of any thereof.

At least a portion of the surface of the cured encapsulating material can be surface treated using a texturing process. The texturing process can be used as a treatment of the surface of the encapsulating material alone or in combination with a surface treatment using a corona discharge, a plasma, an ultraviolet ozone, a plume discharge, a brush discharge, a glow discharge, a luminous discharge, and/or a primer coating. As used herein, the term “texturing” refers to the process of providing a topological variation in the surface of a material. For example, texturing a surface of an encapsulating material can comprise overlaying a layer of fabric across the surface of the encapsulating material and subsequently removing the fabric after thermosetting to provide an embedded or imprinted pattern in the surface of the thermoset encapsulating material. Other examples of the texturing process of the surface of the encapsulating material can comprise an embossing or, imprinting process, a carving or shaping process, scoring, burning, and/or cutting, a cross-hatch or other pattern, a grid, striations, ridges, or the like, placed into or onto the surface of the cured encapsulating material. The texturing process can comprise texturing at least a portion of a surface of the encapsulating material before, during, and/or after curing the encapsulating material. The texturing process of the invention can comprise texturing at least a portion of a surface of the encapsulating material before, during, and/or after additional treating of the cured encapsulating material, e.g. with the corona discharge, the plasma, and/or the ultraviolet ozone.

The back coat can comprise a cured polyurea resin formed from a liquid coating composition comprising a polyisocyanate, a polyamine, a diamine chain extender and optionally an amine-functional silicone different from the polyamine and/or hydroxy-functional silicone. For example, the back coat 210 can comprise a polyurea layer as described in U.S. patent application Ser. No. 14/484,919 which is incorporated by reference into this specification. The coating composition can comprise an aliphatic composition comprising a polyamine comprising a polyaspartic ester or a cyclo-aliphatic polyaspartic ester, a diamine chain extender comprising an aliphatic cyclic secondary amine, and an amine-functional siloxane.

Physical and chemical advantages of the back coat can include robust application, impact protection, high durability and resistance to abrasion, and chemical and weather resistance. The back coat can function to protect the photovoltaic cell and/or the photovoltaic module from abrasion, erosion, and/or environmental damage, and can provide a moisture barrier, durability, and/or extended life to the photovoltaic module. The term “resin,” as used herein, refers to compounds comprising a liquid composition that can harden into a solid.

As used herein, the term “isocyanate” includes unblocked isocyanate compounds capable of forming a covalent bond with a reactive group such as a hydroxyl, thiol or amine functional group. Thus, isocyanate can refer to “free isocyanate”, which will be understood to those skilled in the art. The isocyanate can be monofunctional (containing one isocyanate functional group (NCO)). The isocyanate can be blocked and/or include combinations of any isocyanates and/or isocyanate functional prepolymers. As used herein, the term “polyisocyanate” refers to an isocyanate that can be polyfunctional (containing two or more isocyanate functional groups (NCOs)). Polyisocyanates include diisocyanates and diisocyanate reaction products comprising, for example, biuret, isocyanurate, uretdione, urethane, urea, iminooxadiazine dione, oxadiazine trione, carbodiimide, acyl urea, allophanate groups, and combinations of any thereof. The polyisocyanates can be aromatic or aliphatic including a mixture of aromatic and aliphatic polyisocyanates.

Suitable isocyanates and polyisocyanates can be numerous and can vary widely. Such isocyanates can include those that are known in the art. Non-limiting examples of suitable isocyanates can include monomeric and/or polymeric isocyanates. The isocyanates can be selected from monomers, prepolymers, oligomers, or blends thereof. The isocyanate of the invention can be C₂-C₂₀ linear, branched, cyclic, aromatic, aliphatic, or combinations of any thereof.

Suitable isocyanates for use in the invention can include but are not limited to isophorone diisocyanate (IPDI), which can be 3,3,5-trimethyl-5-isocyanato-methyl-cyclohexyl isocyanate; hydrogenated materials such as cyclohexylene diisocyanate, 4,4′-methylenedicyclohexyl diisocyanate (H₁₂MDI); mixed aralkyl diisocyanates such as tetramethylxylyl diisocyanates, OCN—C(CH₃)₂—C₆H₄C(CH₃)₂—NCO; polymethylene isocyanates such as 1,4-tetramethylene diisocyanate, 1,5-pentamethylene diisocyanate, 1,6-hexamethylene diisocyanate (HMDI), 1,7-heptamethylene diisocyanate, 2,2,4- and 2,4,4-trimethylhexamethylene diisocyanate, 1,10-decamethylene diisocyanate and 2-methyl-1,5-pentamethylene diisocyanate, and mixtures of any thereof.

Non-limiting examples of aromatic isocyanates for use in the invention can include but are not limited to phenylene diisocyanate, toluene diisocyanate (TDI), xylene diisocyanate, 1,5-naphthalene diisocyanate, chlorophenylene 2,4-diisocyanate, bitoluene diisocyanate, dianisidine diisocyanate, tolidine diisocyanate, alkylated benzene diisocyanates, methylene-interrupted aromatic diisocyanates such as methylenediphenyl diisocyanate, 4,4′-isomer (MDI) including alkylated analogs such as 3,3′-dimethyl-4,4′-diphenylmethane diisocyanate, polymeric methylenediphenyl diisocyanate, and mixtures of any thereof.

An isocyanate monomer can be used in the invention. It is believed that the use of an isocyanate monomer (i.e., residual-free monomer from the preparation of prepolymer) can decrease the viscosity of the polyurea composition thereby improving its flow ability, and can provide improved adhesion of the polyurea coating to a previously applied coating and/or to an uncoated substrate. At least 1 percent by weight, or at least 2 percent by weight, or at least 4 percent by weight of the isocyanate component can comprise at least one isocyanate monomer.

The isocyanate can include oligomeric isocyanate such as but not limited to dimers such as the uretdione of 1,6-hexamethylene diisocyanate, trimers such as the biuret and isocyanurate of 1,6-hexanediisocyanate and the isocyanurate of isophorone diisocyanate, allophonates and polymeric oligomers. Modified isocyanates can also be used, including but not limited to carbodiimides and uretone-imines, and mixtures of any thereof. Suitable materials include, without limitation, those available under the designation DESMODUR from Bayer Corporation of Pittsburgh, Pa., U.S.A., and include DESMODUR N 3200, DESMODUR N 3300, DESMODUR N 3400, DESMODUR XP 2410 and DESMODUR XP 2580.

The isocyanate component of the invention can comprise an isocyanate functional prepolymer formed from a reaction mixture comprising an isocyanate and another material. Any isocyanate known in the art, such as any of those described above, can be used in the formation of the prepolymer. As used herein, an isocyanate functional prepolymer refers to the reaction product of isocyanate with polyamine and/or other isocyanate reactive group such as polyol; the isocyanate functional prepolymer has at least one isocyanate functional group (NCO).

An isocyanate functional prepolymer can comprise isocyanate that can be pre-reacted with a material comprising a flame retardant material, such as a phosphorus-containing. polyol. Suitable isocyanate functional prepolymers comprising a flame retardant material are disclosed in Paragraphs [0017]-[0023] of U.S. Ser. No. 12/122,980, incorporated by reference herein. As described in that excerpt, the phosphorus containing polyol can itself be the reaction product of a phosphorus containing polyol, sometimes referred to as an “initial” phosphorus containing polyol, and another compound.

However, the polyol used in the formation of the pre-polymer may not comprise a phosphorus containing polyol. Suitable non-phosphorus containing polyols can include polytetrahydrofuran materials such as those sold under the tradename TERATHANE (e.g., TERATHANE 250, TERATHANE 650, and TERATHANE 1000 available from Invista Corporation).

The amine component can comprise a suitable amine. At a temperature ≧7° C., such as a temperature ranging from 7° C. to 13° C., the viscosity of the second component can be ≦1700 centipoise, such as ≦1500 centipoise or ≦1000 centipoise. The amine component can be referred to herein as a “curative” because it will react or cure with the isocyanate to form a polyurea. The ratio of equivalents of isocyanate groups to equivalents of amine groups can be greater than 1 and the isocyanate component and the amine component can be applied to a substrate at a volume mixing ratio of 1:1.

As used herein, the term “polyamine” refers to compounds comprising at least two free primary and/or secondary amine groups. Suitable polyamines are numerous and can vary widely. Such polyamines can include those that are known in the art. Non-limiting examples of suitable polyamines can include but are not limited to primary and secondary amines, and mixtures of any thereof, such as any of those listed herein. Amine terminated polyureas can also be used. Amines comprising tertiary amine functionality can be used provided that the amine further comprises at least two primary and/or secondary amino groups. In the invention, wherein the isocyanate functional prepolymer comprises a polyamine, the ratio of equivalents of isocyanate groups (NCOs) to equivalents of amine groups (NHs) can be greater than 1.

The amine can include, for example, monoamines, or polyamines having at least two functional groups such as di-, tri-, or higher functional amines, and mixtures of any thereof. Further, the amine can be aromatic or aliphatic such as cycloaliphatic, or mixtures of any thereof. Non-limiting examples of suitable monoamines can include aliphatic polyamines such as, but not limited to, ethylamine, isomeric propylamines, butylamines, pentylamines, hexylamines, cyclohexylamine, and benzylamine. Suitable primary polyamines include, but are not limited to, ethylene diamine, 1,2-diaminopropane, 1,4-diaminobutane, 1,3-diaminopentane (DYTEK EP, Invista), 1,6-diaminohexane, 2-methyl-1,5-pentane diamine (DYTEK A, Invista), 2,5-diamino-2,5-dimethylhexane, 2,2,4- and/or 2,4,4-trimethyl-1,6-diamino-hexane, 1,11-diaminoundecane, 1,12-diaminododecane, 1,3- and/or 1,4-cyclohexane diamine, 1-amino-3,3,5-trimethyl-5-aminomethyl-cyclohexane, 2,4- and/or 2,6-hexahydrotoluylene diamine, 2,4′-diaminodicyclohexyl methane, 4,4′-diaminodicyclohexyl methane (PACM-20, Air Products) and 3,3′-dialkyl-4,4′-diaminodicyclohexyl methanes (such as 3,3′-dimethyl-4,4′-diaminodicyclohexyl methane (DIMETHYL DICYKAN or LAROMIN C260, BASF; ANCAMINE 2049, Air Products) and 3,3′-diethyl-4,4′-diaminodicyclohexyl methane), 2,4-and/or 2,6-diaminotoluene, 3,5-diethyltoluene-2,4-diamine, 3,5-diethyltoluene-2,6-diamine, 3,5-dimethylthio-2,4-toluenediamine, 3,5-dimethylthio-2,4-toluenediamine, 2,4′- and/or 4,4′-diaminodiphenyl methane, dipropylene triamine, bis hexamethylene triamine, or combinations of any thereof. Polyoxyalkyleneamines are also suitable. Polyoxyalkyleneamines comprise two of more primary or secondary amino groups attached to a backbone, derived, for example, from propylene oxide, ethylene oxide, butylene oxide or a mixture thereof. Examples of such amines include those available under the designation JEFFAMINE, such as, without limitation, JEFFAMINE D-230, D-400, D-2000, HK-511, ED-600, ED-900, ED-2003, T-403, T-3000, T-5000, SD-231, SD-401, SD-2001, and ST-404 (Huntsman Corporation, The Woodlands, Tex., USA). Such amines have an approximate molecular weight ranging from 200 to 7500.

Polyamines used in the invention can include polyaspartic esters, more specifically polyaspartic esters having the structure:

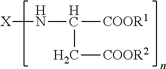

wherein n is an integer of 2 to 4, X represents an organic group which has a valency of n that is inert to isocyanate groups. X can be an aliphatic residue such as a cycloaliphatic residue. The term “cycloaliphatic” as used herein means an aliphatic structure comprising one or more non-aromatic hydrocarbon rings and optionally also noncyclic aliphatic carbon chains. Secondary cycloaliphatic diamines can also be used. Suitable cycloaliphatic diamines include, without limitation, JEFFLINK 754 (Huntsman Corporation, The Woodlands, Tex., USA), CLEARLINK 1000 (Dorf-Ketal Chemicals, LLC), and aspartic ester functional amines, such as those available under the name DESMOPHEN such as DESMOPHEN NH1220, DESMOPHEN NH 1420, and DESMOPHEN NH 1520 (Bayer Materials Science LLC.). Other suitable secondary amines that can be used include the reaction products of materials comprising primary amine functionality, such as those described herein, with acrylonitrile. For example, the secondary amine can be the reaction product of 4,4′-diaminodicyclohexylmethane and acrylonitrile. Alternatively, the secondary amine can be the reaction product of isophorone diamine and acrylonitrile, such as POLYCLEAR 136 (available from BASF/Hansen Group LLC).

Other amines that can be used include adducts of primary polyamines with mono or polyepoxies such as the reaction product of isophorone diamine with CARDURA E-10P. Additional amines can comprise trifunctional primary polyoxypropylenediamine, or a primary trifunctional aliphatic polyether amine. Combinations of different polyamines including combinations of any of the polyamines mentioned above can be used.

The present polyurea compositions can also comprise one or more amines such as those describe in U.S. patent application Ser. Nos. 11/611,979, 11/611,984, 11/611,988, 11/611,982, and 11/611,986, all of which are incorporated in pertinent part herein by reference.

The phrase “diamine chain extender” used herein refers to difunctional polyamines that assist in polymeric extension of the molecules within a back coat. The diamine chain extender includes primary diamines, secondary diamines, diamines comprising both a primary and a secondary amino group, diimines, and combinations of any thereof. The amino groups (including secondary and primary amino groups) or imino groups can be bound to an aliphatic residue such as a cycloaliphatic residue or a noncyclic aliphatic residue. Thus, the diamine chain extender can include an aliphatic primary diamine, an aliphatic secondary diamine, a cycloaliphatic primary diamine, a cycloaliphatic secondary diamine, a noncyclic aliphatic primary diamine, a non-cyclic aliphatic secondary diamine, an aliphatic diimine, and combinations of any thereof. Specific examples of diamine chain extenders include cycloaliphatic secondary diamines derived from isophorone such as JEFFLINK® 754 Diamine, available from Huntsman Corporation, The Woodlands, Tex., USA.

Optionally, the silocone polymer can comprise an amine-functional and/or a hydroxy-functional silicone. As used herein, the term “silicone” refers to a polyorganosiloxane (also termed “polysiloxane” or “siloxane”) which can be an oligomer or polymer. As used herein, the term “hydroxy-functional silicone” refers to a silicone having hydroxyl groups. The invention can comprise an amine-functional and/or hydroxy-functional silicone to improve the physical properties and long-term performance of the back coat. As used herein, the terms “amine-functional silicone” refers to a silicone having primary and/or secondary amine groups. The invention can comprise an amine functional and/or hydroxy-functional silicone to improve the physical properties and long-term performance of the back coat.

A cured fluoropolymer resin can be used as an alternative to the polyurea resin. As used herein, the term “fluoropolymer” refers to a fluorocarbon based polymer with multiple strong carbon-fluorine bonds. Fluoropolymers can be characterized by a high resistance to solvents, acids, and bases. Fluoropolymers can be made from monomers such as vinyl fluoride, vinylidene fluoride, tetrafluoroethylene, hexafluoropropylene, perfluoropropylvinylether, perfluoromethylvinylether, chlorotrifluoro-ethylene and can be co-polymers with non-fluorinated monomers such as ethylene and propylene.

Any suitable fluoropolymer can be used according to the invention. Examples include but are not limited to perfluoroalkoxy tetrafluoroethylene copolymer (PFA), ethylenechlorotrifluoroethylene (E-CTFE), ethylenetetrafluoroethylene (E-TFE), poly(vinylidene fluoride) (PVDF), poly(tetrafluoroethylene), poly(vinyl fluoride), poly(trifluoroethylene), poly(chlorotrifluoroethylene) (CTFE), and/or poly(hexafluoropropylene). Mixtures of two or more suitable fluoropolymers can be used, as can copolymers, terpolymers and the like of suitable fluoropolymers. The qualities of fluoropolymer resins and oligomeric additives make them an ideal solution for applications requiring a high resistance to solvents, acids and bases, and an ability to significantly reduce friction Such surfactant additives reduce surface energy while increasing chemical, UV, moisture, grease and dirt resistance and surface lubricity. For example, CORAFLON® is a fluoropolymer resin commercially available from PPG Industries, Inc., Pittsburgh, Pa., USA.

Photovoltaic modules produce electricity by converting electromagnetic energy into electrical energy. To survive in harsh operating environments, photovoltaic modules use encapsulant materials to provide durability and module life. “Encapsulant,” “encapsulated,” “encapsulating,” and like terms refer to the covering of a component such as a photovoltaic cell with a layer or layers of material such that the surface of the component is not exposed in order to protect the photovoltaic cell from the environment. The “backing layer,” “backsheet,” “back coat” or like terms as used herein refers to a layer that can be located on the side of the photovoltaic cell opposite the front transparency.

As used herein, the term “encapsulating material” refers to polymeric materials used to adhere photovoltaic cells to front transparencies and/or back sheets in photovoltaic modules, and/or encapsulate photovoltaic cells within a covering of polymeric material. The encapsulating material can comprise a silicone encapsulant such as Dow Corning PV 6150 Cell Encapsulant, commercially available from Do Corning Corporation, Midland, Mich., USA. The encapsulating material can further comprise an adhesion promoting additive.

As used herein, the term “adhesion promoting additive” refers to a composition, element, component, or the like that can be added to the encapsulant or encapsulating material to promote adhesion to the encapsulating surface. The adhesion promoting additive can comprise an isocyanate-functional silane, a hydroxy-functional silane, an amine-functional silane, or combinations of any thereof. As used herein, the term “hydroxy-functional silane” refers to polysilane oligomers or polymers having a hydroxyl functional group. As used herein, the term “amine-functional silane” refers to polysilane oligomers or polymers having primary and/or secondary amine groups. As used herein, the term “isocyanate-functional silane” refers to polysilane oligomers or polymers having an isocyanate functional group.

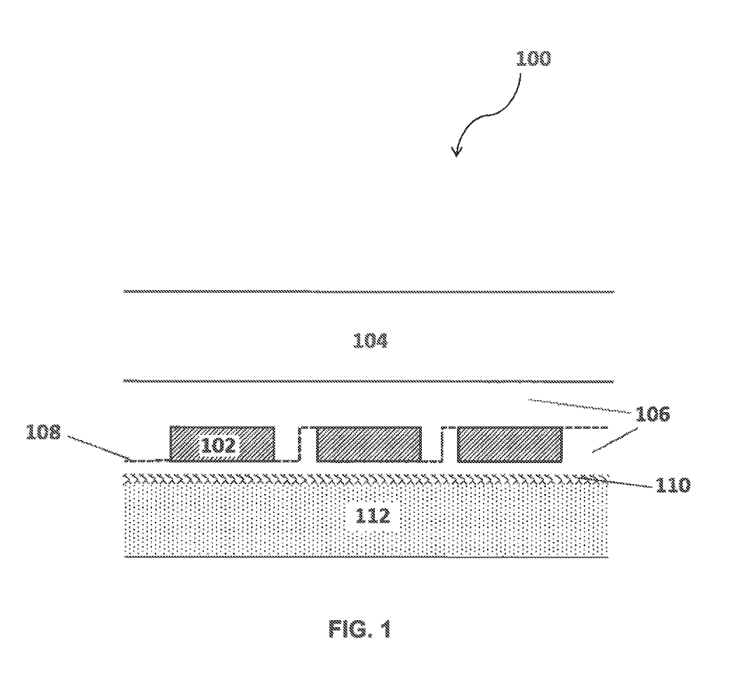

As schematically illustrated in FIG. 1, a photovoltaic module can include a bulk photovoltaic module 100 comprising a plurality of electrically interconnected photovoltaic cells 102 adhered to a front transparency 104. The photovoltaic cells 102 can be positioned such that a front contact (not shown) of the photovoltaic cells 102 can be facing the front transparency 104. The photovoltaic module 100 can further include an encapsulating material 106 adjacent to the front transparency 104. The encapsulating material 106 can provide adhesion of the photovoltaic cells 102 to the front transparency 104. The photovoltaic module 100 can further comprise electrical interconnections 108 that link or connect the photovoltaic cells 102 applied to the encapsulating material 106. As shown in FIG. 1, the encapsulating material 106 encapsulates at least a portion of the front transparency 104, the electrical interconnections 108 and the photovoltaic cells 102. The photovoltaic cell 102 can comprise a crystalline silicon wafer. The encapsulating material 106 can comprise a treated surface 110 of the encapsulating material 106 opposite the front transparency 104. The treated surface 110 of the encapsulating material 106 can comprise a surface of a cured layer formed from a liquid coating composition, wherein at least a portion of the surface can be treated with a corona discharge, plasma, an ultraviolet ozone, a plume discharge, a brush discharge, a glow discharge, a luminous discharge, or combinations of any thereof. The photovoltaic module 100 can further comprise a back coat 112 deposited on at least a portion of the encapsulating material 106, the treated surface 110 of the encapsulating material, or combinations of any thereof.

The photovoltaic module 100 can further comprise the encapsulating material 106 adjacent to the front transparency 104. The encapsulating material 106 can be applied or deposited onto at least a portion of the front transparency 104. The encapsulating material can encapsulate at least a portion of a photovoltaic cell 102. Further, the encapsulating material 106 can comprise a silicone encapsulant such as Dow Corning PV 6150. The encapsulating material can comprise a silicone encapsulant and an adhesion promoting additive.

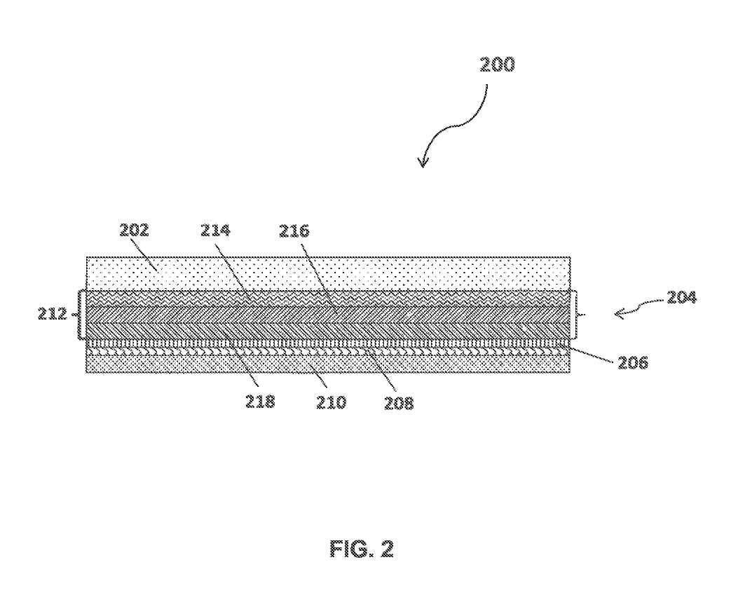

Photovoltaic cells 102 and the electrical interconnections 108 can be positioned on the encapsulant layer 106 so that each photovoltaic cell 102 can be electrically connected to another cell. Photovoltaic cells 102 include constructs comprising a semiconductor wafer positioned in between two electrically conducting contacts. The semiconductor wafer of the invention can comprise a crystalline silicon wafer. The first electrically conducting contact can comprise a transparent conducting oxide film layer deposited onto one side of the crystalline silicon wafer or semiconductor wafer. The second electrically conducting contact can comprise a metallic layer deposited onto an opposite side of the crystalline silicon wafer or semiconductor wafer. Photovoltaic cells 102 can comprise bulk photovoltaic cells (e.g., ITO- and aluminum-coated crystalline silicon wafers). The invention can comprise an assembly of the photovoltaic cells 102 and the electrical interconnections 108. The photovoltaic module 100 can comprise multiple bulk photovoltaic cells that each can comprise a crystalline silicon wafer. The photovoltaic cell can comprise multiple thin film photovoltaic cells that each can comprise a plurality of deposited photovoltaic layers (see FIG. 2).

The photovoltaic module 100 can further comprise a treated surface 110 of the cured encapsulating material 106 comprising a surface treated using any surface treatment and/or any combination of surface treatments as previously described herein.

The photovoltaic module 100 can further comprise a protective coating or back coat 112. The back coat 112 can comprise a single coating layer or a plurality of coating layers. The back coat 112 can be derived from any number of coatings, including powder coating compositions, liquid coating compositions and/or electrodeposited coatings. A durable, moisture resistant and/or abrasion resistant protective coating can be used as a backing or encapsulant layer to reduce or eliminate corrosion associated with photovoltaic cell failure.

Although the photovoltaic module 100 is illustrated in FIG. 1 as a bulk photovoltaic module, the photovoltaic module can comprise a thin film photovoltaic module. As shown in FIG. 2, a thin film photovoltaic module 200 can comprise a module including a front transparency 202, a photovoltaic cell 204, an encapsulating material 206 deposited on a portion of the photovoltaic cell 204 and the front transparency 202, a treated surface 208 of the encapsulating material 206, and a back coat 210 deposited on the treated surface 208.

The front transparency 202 can comprise a material that can be transparent to electromagnetic radiation in a wavelength range that can be absorbed by the photovoltaic cell 204 and used to generate electricity. The front transparency can comprise a planar sheet of transparent material comprising the outward-facing surface of a photovoltaic module 200. The front transparency 202 can comprise the same or similar materials and can perform the same or similar functions as the front transparency 104 as described above in connection with the bulk photovoltaic module 100 shown in FIG. 1.

The thin film photovoltaic module 200 of FIG. 2 can be fabricated by deposition of multiple thin film photovoltaic cells 204 that each can comprise a plurality of deposited photovoltaic layers 212 onto the front transparency 202. The plurality of deposited photovoltaic layers 212 can include a transparent conducting oxide layer or other transparent conducting film 214. The transparent conducting film 214 can be optically transparent and/or electrically conductive providing a junction between the front transparency 202 and a semiconductor active material layer 216. The transparent conducting film 214 can act as a window for the passage of light through to the semiconductor active material layer 216 beneath and/or can act as an ohmic contact for electron transport out of the photovoltaic module 200. The transparent conducting film 214 can be fabricated from materials that have greater than 80% transmittance of incident light as well as conductivities greater than 103 S/cm for efficient electron/hole transport. For example, the transparent conducting film 214 can include a transparent conducting oxide comprising one of indium tin oxide, fluorine doped tin oxide, doped zinc oxide, or combinations of any thereof. The transparent conducting film 214 can be deposited or grown onto the front transparency 202 using a variety of deposition techniques. For example, the transparent conducting film can be deposited using aerosol-assisted pyrolytic deposition, metal organic chemical vapor deposition (MOCVD), metal organic molecular beam deposition (MOMBD), spray pyrolysis, pulsed laser deposition (PLD), fabrication techniques involving magnetron sputtering of the film, or combinations of any thereof.

The transparent conducting film 214 can be in direct contact with the semiconductor active material layer 216. The semiconductor active material layer 216 can comprise a layer of photovoltaic semiconducting material (e.g., amorphous silicon, cadmium telluride, copper indium diselenide, or combinations of any thereof) deposited onto the transparent conducting film 214. The semiconductor active material layer 216 can function to produce electrons available for conduction through the photovoltaic module 200.

The semiconductor active material layer 216 can be in direct contact with a metallic layer 218. The metallic layer 218 can comprise, for example, aluminum, nickel, molybdenum, copper, silver, gold, or combinations of any thereof. The metallic layer 218 can function as a back contact to the semiconductor active material layer 216 for conduction of electrical current throughout the photovoltaic module 200. The metallic layer 218 can be deposited onto the semiconductor active material layer 216 using a variety of deposition techniques. For example, the metallic layer 218 can be deposited onto the semiconductor active material layer 216 using screen printing, thermal spray coating, vapor deposition, chemical vapor deposition, or combinations of any thereof. The metallic layer 218 can be in direct contact with the encapsulating material 206.

The photovoltaic module 200 can further comprise the encapsulating material 206 adjacent to the thin film photovoltaic cells 204. The encapsulating material 206 can be deposited on at least a portion of the photovoltaic cell 204 and the front transparency 202. For example, the encapsulating material 206 encapsulates a photovoltaic cell comprising a thin film photovoltaic cell 204 directly adhered to the front transparency 202. The encapsulating material 206 can comprise the same or similar materials and performs the same or similar functions as the encapsulating material 106 as described above in connection with the bulk photovoltaic module 100 shown in FIG. 1. Further, the encapsulating material 206 can comprise a cured clear encapsulating coating deposited onto at least a portion of one side of the thin film photovoltaic cells 204. The encapsulating material can comprise a cured and treated clear encapsulating coating.

The encapsulating material 206 surface opposite the thin film photovoltaic cell 204 can be treated to increase the surface energy in order to improve wettability and adhesion properties. Thus, the thin film photovoltaic cell 204 can further comprise a treated surface 208 of the cured encapsulating material 206 comprising a surface treated using any surface treatment and/or any combination of surface treatments as previously described herein. For example, the encapsulating material 206 can comprise a cured and corona discharge, plasma, and/or ultraviolet ozone treated silicone encapsulant. The treated surface 208 can be in direct contact with the back coat 210.

The back coat 210 can comprise a cured polyurea layer formed from a liquid coating composition. As used herein, the term “liquid coating” refers to a coating composition in the liquid state comprising a fixed volume. The back coat 210 of the invention can comprise a polyurea layer formed from a spray applied and cured coating composition. The back coat 210 can comprise a cured polyurea layer formed from a liquid coating composition comprising a polyisocyanate, a polyamine, a diamine chain extender, and an amine-functional and/or hydroxy-functional silicone, or combinations of any thereof.

Moisture barrier requirements can be higher for the thin film photovoltaic module 200 than for the bulk photovoltaic module 100. For example, Copper Indium Gallium Selenide (CIGS) and CdTe thin film photovoltaic modules can include thin transparent conducting oxide layers within the plurality of deposited photovoltaic layers that can be susceptible to moisture and oxygen. In order to provide a high moisture and oxygen barrier, the thin film photovoltaic modules can comprise a glass front transparency, a glass back sheet, and an edge seal. For example, the back coat 210 can be in direct contact with the glass back sheet (not shown). In contrast, although moisture can eventually cause corrosion of the tabbing ribbon and bus bars, bulk photovoltaic modules do not have the same sensitivity to moisture as thin film photovoltaic modules. Thus, in order to provide moisture protection the bulk photovoltaic module can include a glass front transparency and a polymeric back sheet. For example, a crystalline silicon bulk photovoltaic module can comprise a glass front transparency and a polymeric back sheet comprising polyethylene terephthalate (PET) including a fluoropolymer layer. The back coat 112 of the bulk photovoltaic module 100 can be in direct contact with the polymeric back sheet (not shown).

Referring back to FIG. 1, depositing the back coat 112 can comprise depositing a liquid coating composition onto at least a portion of the treated encapsulating material 110 and curing the liquid coating composition to form the back coat 112. For example, depositing the back coat 112 can comprise depositing the liquid coating composition onto at least a portion of the photovoltaic cells 102 and the electrical interconnections 108 and curing the liquid coating composition to form the cured back coat 112. Depositing the back coat 112 can comprise depositing the liquid coating composition onto at least a portion of the back side of the photovoltaic cell 102 opposite the front transparency 104 and onto the treated surface 110 of the cured encapsulating material 106 and curing the liquid coating composition to form the cured back coat 112.

A problem with prior two- or more-component polyurea resin coating systems and compositions can be that the combined liquid coating compositions can rapidly gel and cure, which can limit pot life. Aliphatic primary polyamines, for example, can react rapidly with polyisocyanates, which can limit their commercial applications. However, efforts to decrease the crosslinking rate of the polyisocyanates and polyamines that form polyurea resin coatings, thereby increasing the pot life of the mixed coating composition, also tend to simultaneously increase the cure time of a liquid coating applied to a substrate.

Polyamines can confer advantageous properties to the back coat. For example, a polyamine component can reduce drying and/or curing times, provide for curing at ambient temperatures, and confer impact, abrasion, corrosion, chemical, and weather resistance. Polyamines can be formulated with slower reaction rates to accommodate batch-mixing and thinner film application. Further, polyamine coatings can be UV and light stable and can provide the beneficial properties of polyurea resin (rapid curing, robust application, and 100% solids) with controlled moisture vapor transmission rate (MVTR) permeance. Thus, the back coat can provide for rapid curing at ambient temperatures and control of gel time. For example, the back coat can provide a curing time of 5-60 seconds with a gel time of 5-120 seconds.

The liquid coating compositions of the invention can be applied or deposited onto all or a portion of the back side of the cured encapsulating material of the photovoltaic module, the photovoltaic cells, and the electrical interconnections, and cured to form the back coat or layer thereon (e.g., topcoat, primer coat, tie coat, clear coat, or the like) using any suitable coating application technique. For example, the coatings of the present disclosure can be applied by spraying, dipping, rolling, brushing, roller coating, curtain coating, flow coating, slot die coating, and the like, and combinations of any thereof.

In the method of the invention, wherein an encapsulant layer comprises a flowable coating composition applied to one side of a front transparency, the flowable coating composition can be applied using any of the above-described coating application techniques.

The back coat can exhibit a Young's modulus in a range of 10 MPa to 900 MPa, or any sub-range subsumed therein, such as, for example, 10 to 800 MPa, 100 to 500 MPa, 200 to 400 MPa, or 50 to 700 MPa. Young's modulus values were determined in accordance with the ASTM D 882-02 Standard Test Method for Tensile Properties of Thin Plastic Sheeting developed by ASTM International, West Conshohocken, Pa., USA.

The back coat can reach elongation in the range of 10% to 300%, or any sub-range subsumed therein, such as, for example, 10% to 50%, 15% to 25%, 18% to 24%, or 100% to 200%. Elongation values were determined in accordance with the ASTM D 882-02 Standard Test Method for Tensile Properties of Thin Plastic Sheeting developed by ASTM International, West Conshohocken, Pa., USA.

The back coat can exhibit a tensile strength in a range of 10 MPa to 900 MPa, or any sub-range subsumed therein, such as, for example, 5 MPa to 100 MPa, 100 MPa to 500 MPa, 10 MPa to 200 MPa or 50 MPa to 100 MPa. Tensile strength values were determined in accordance with the ASTM D 882-02 Standard Test Method for Tensile Properties of Thin Plastic Sheeting developed by ASTM International, West Conshohocken, Pa., USA.

The back coat can exhibit a dry film thickness in the range of 0.5 to 50 mils, or any sub-range subsumed therein, such as, for example, 5 to 40 mils, 10 to 25 mils, 10 to 20 mils, or 10 to 15 mils. Dry film thickness values were determined using a Marathon Electronic digital micrometer, C0030025.

The back coat can exhibit a moisture vapor transition rate permeance in the range of 1 to 1000 g*mil/m²*day, or any sub-range subsumed therein, such as, for example, 100 to 500 g*mil/m²*day, 50 to 400 g*mil/m²*day, 5 to 50 g/m²/day, or 20 to 40 g*mil/m²*day. Moisture vapor transition rate permeance was measured with a Lyssy L80-5000 water vapor permeability tester and values were determined in accordance with the ASTM E-398 Standard Test Method for Water Vapor Transmission Rate of Sheet Materials Using Dynamic Relative Humidity Measurement developed by ASTM International, West Conshohocken, Pa., USA.

The back coat can exhibit a maximum permeance value ranging from 1 to 1,000 g*mil/m2*day, or any sub-range subsumed therein, such as, for example, 1 to 500 g*mil/m2*day, 100 to 500 g*mil/m2*day, 500 to 1,000 g*mil/m2*day, or 250 to 750 g*mil/m2*day.

The back coat can exhibit a dry insulation resistance of greater than 400 MΩ, or, can be greater than 500 MΩ, greater than 1000 MΩ, greater than 1500 MΩ, or greater than 2000 MΩ. The above dry insulation resistance properties can be exhibited by a back coat having a dry film thickness less than 30 mils or less than 25 mils, or less than 20 mils. For example, a less than 30 mils, less than 25 mils, or less than 20 mils thick back coat can exhibit a dry insulation resistance greater than 500 MΩ, greater than 1000 MΩ, greater than 1500 MΩ, or greater than 2000 MΩ. Dry insulation resistance was measured using a DI-2000M insulation tester and values were determined in accordance with the International Electrotechnical Commission (IEC), International Standard, Second Edition (2005-04), “Crystalline silicon terrestrial photovoltaic (PV) modules—Design qualification and type approval” (IEC 61215:2005).

The back coat can include a topcoat that can comprise a dry (cured) film thickness ranging from 0.2 mils to 25 mils, or any sub-range subsumed therein, such as, for example, 1 mils to 10 mils, 0.5 mils to 15 mils, 10 mils to 20 mils, or 5 mils to 8 mils. The back coat can comprise a two- or more-layer system comprising an underlying layer and one- or more-overlying layers. The underlying layer(s) in between a topcoat, layer of cured encapsulant, photovoltaic cells, and electrical interconnects can have a dry (cured) film thickness ranging from 0.2 mils to 10 mils, or any sub-range subsumed therein, such as, for example, 1 mils to 2 mils, 0.5 mils to 5 mils, 2.5 mils to 7 mils, or 7 mils to 10 mils. A two- or more-layer back coat system comprising at least a topcoat and an underlying layer can together have a dry (cured) film thickness ranging from 0.5 mils to 50 mils, or any sub-range subsumed therein, such as, for example, 1 mils to 10 mils, 10 mils to 40 mils, 25 mils to 35 mils, or 5 mils to 8 mils. Dry film thickness values were determined using a Marathon Electronic digital micrometer, C0030025.

It can be contemplated that the coating methods described herein can employ coating compositions that can be applied over all or at least a portion of a substrate and cured to form a coat or layer thereon (e.g., topcoat, primer coat, tie coat, clearcoat, or the like). The applied coats can then form a coating system over all or at least a portion of a substrate and cured which, individually, as a single coat, or collectively, as more than one coat, comprise a protective barrier over at least a portion of the substrate. One such coat can be formed from a liquid encapsulant which cures to form a transparent partial or solid coat on at least a portion of a substrate (i.e., a liquid encapsulant material or clearcoat).

The back coat can provide an overcoat or protective and/or durable coating. The back coat can comprise the outermost backing layer of a photovoltaic module in accordance with the description in this specification. The back coat can comprise multiple coats, wherein any coat or coats can individually comprise the same or different coating compositions. A photovoltaic module can comprise a topcoat as the outermost backing layer of the photovoltaic module, unlike some photovoltaic module designs that rely on a film that can be laminated and/or a back sheet (such as glass, metal, etc.).

The photovoltaic modules 100 and 200 can comprise an outermost electrocoat as described in co-pending U.S. patent application Ser. No. 14/484,803, “Electrocoated Photovoltaic Modules and Methods of Making Same” to Shao et al., which is incorporated by reference into this specification.

The back coat 112 or 210 alone or in combination with a primer coating and/or other coatings can comprise a primer-topcoat system (not shown) that can be applied to coat the treated surface 110 or 208 of the encapsulating material 106 or 206 of photovoltaic module 100 or 200 (shown in FIG. 1). The primer-topcoat system can comprise one, two, or more coats, wherein any coat or coats can individually comprise the same or a different coating composition. The coatings used to produce the layers of coats (e.g., primer coat, tie coat, topcoat, monocoat, and the like) comprising a protective coating system for a photovoltaic module can comprise inorganic particles in the coating composition and the resultant cured back coat. As used herein, tie coat refers to an intermediate coating intended to facilitate or enhance adhesion between an underlying coating (such as a primer coat or an electrocoat) and an overlying back coat.

The coatings (e.g., back coats 112 and 206 and/or any underlying primer or tie coats), can comprise particulate mineral materials, such as, for example, mica, which can be added to the coating compositions used to produce a protective coating system for photovoltaic modules 100 or 200. The inorganic particles can comprise aluminum, silica, such as fumed silica, clays, pigments, and/or glass flake, or combinations of any thereof. Inorganic particles can be added to the primer coat, tie coat, back coat, topcoat and/or monocoat applied on to the photovoltaic cells 102 or 204 and the electrical interconnections 108 to coat and/or encapsulate these components.

Protective coating systems comprising inorganic particles in the cured coats can exhibit improved barrier properties such as, for example, lower moisture vapor transmission rates and/or lower permeance values. Inorganic particles such as, for example, mica and other mineral particulates, can improve the moisture barrier properties of polymeric films and coats by increasing the tortuosity of transport paths for water molecules contacting the films or coats. These improvements can be attributed to the relatively flat platelet-like structure of various inorganic particles. The inorganic particles can comprise a platelet shape and include an aspect ratio, defined as the ratio of the average width dimension of the particles to the average thickness dimension of the particles, ranging from 5 to 100 microns, or any sub-range subsumed therein. The inorganic particles can have an average particle size ranging from 10 to 40 microns, or any sub-range subsumed therein. Inorganic particle dimensions are readily available from commercial suppliers. For example, particle dimensions contained in TI-PURE® R-900 Titanium Dioxide, a titanium dioxide pigment containing inorganic particles commercially available from DuPont Titanium Technologies, USA, are available through DuPont's product brochures found on the company's website.

The inorganic particles can be added to the back coat to make the cured coating white/reflective without changing the barrier properties of the back coat. For example, titanium dioxide (TiO₂) can be added to make the cured back coat white/reflective without impacting the barrier properties of the cured back coat.

Inorganic particles, such as, for example, mica, can be dispersed in the cured coating layer. The inorganic particles can be mechanically stirred and/or mixed into the coating compositions, or added following creation of a slurry. A surfactant can be used in the invention. Inorganic particles can be mixed until fully distributed in the cured coating layer without settling.

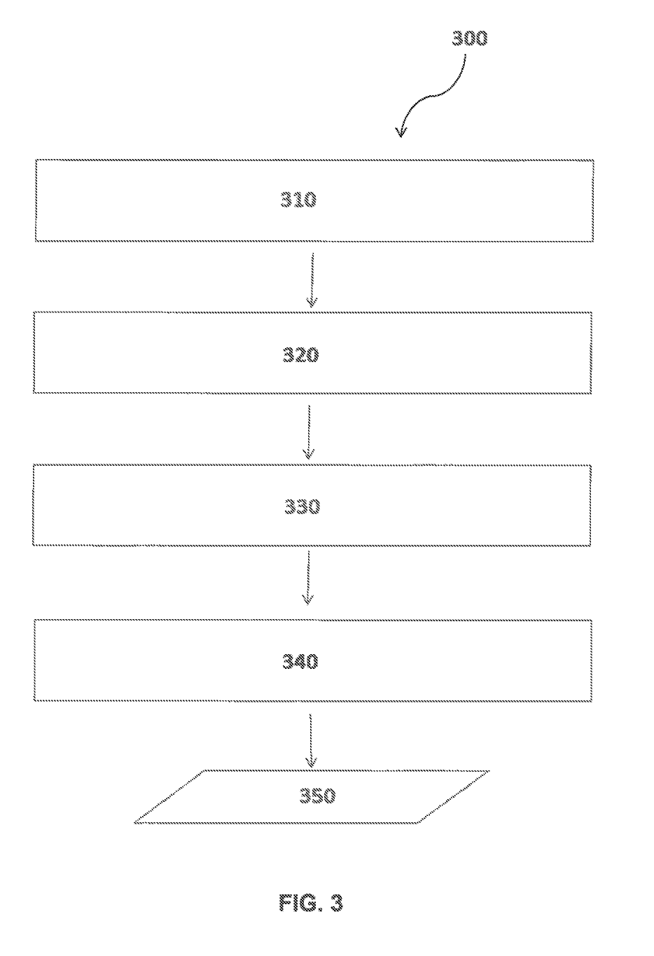

FIG. 3 schematically illustrates a method 300 of production of a photovoltaic module. The method 300 for preparing a photovoltaic module can comprise depositing (step 310) an encapsulating material onto at least a portion of a photovoltaic cell, curing (step 320) the encapsulating material, treating (step 330) at least a portion of a surface of the cured encapsulating material, depositing (step 340) a liquid coating composition onto at least a portion of the treated encapsulating material, and curing (step 350) the liquid coating composition to form a back coat. The encapsulating material can encapsulate at least a portion of the photovoltaic cell. Treating the encapsulating material can comprise treating at least a portion of a surface of the encapsulating material with a corona discharge, a plasma, an ultraviolet ozone, a plume discharge, a brush discharge, a glow discharge, a luminous discharge, or combinations of any thereof. After treating the cured encapsulating material, the method 300 of FIG. 3 can further comprise depositing a primer onto at least a portion of the treated encapsulating material; curing the primer, and depositing a liquid coating composition onto at least a portion of the cured primer.

Moreover, the method 300 can comprise depositing a silicone encapsulant onto at least a portion of a photovoltaic cell, curing the silicone encapsulant, treating at least a portion of a surface of the cured silicone encapsulant with a corona discharge, a plasma, and/or an ultraviolet ozone, depositing a liquid coating composition onto at least a portion of the treated silicone encapsulant, and curing the liquid coating composition t form a back coat. The method 300 can further comprise texturing at least a portion of a surface of the silicone encapsulant before, during, or after treating the cured silicone encapsulant with the corona discharge, the plasma, and/or the ultraviolet ozone.

The cured back coat applied by the method 300 can comprise a polyurea resin. For example, the back coat can comprise a cured layer formed from a liquid coating composition comprising a polyisocyanate, a polyamine, and a diamine chain extender. The liquid coating composition can comprise an amine-functional and/or hydroxy-functional silicone. The liquid coating composition can comprise an amine-functional silicone that can be different from the polyamine and/or a hydroxy-functional silicone. The liquid coating composition can comprise a fluoropolymer resin or a polyurea resin. For example, the liquid coating composition can comprise a polyurea resin formed from a coating composition comprising a polyisocyanate, a polyamine having the structure:

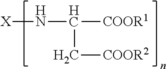

wherein:
n is an integer of 2 to 4
X represents an organic group which has a valency of n that is inert to isocyanate groups, such as an aliphatic residue; and
R¹ and R² represent organic groups that are inert to isocyanate groups;
   a diamine chain extender, and an amine-functional and/or hydroxy-functional silicone, and curing the liquid coating composition to form the back coat.

It is understood that the terms “positioning,” “depositing,” and their grammatical variants, as used herein, refer to placing a referenced component in a spatial relationship with another component, wherein the components can be either placed in direct physical contact or indirectly placed beside each other with an intervening component or space. Accordingly, and by way of example, where a first component is said to be positioned or deposited on, onto, or over a second component, it is understood that the first component can be, but is not necessarily, in direct physical contact with the second component. The terms “positioning” and “depositing can be used interchangeably, but the term “positioning” and its grammatical variants can refer to placing a preexisting component, such as, for example, placing a photovoltaic cell or a pre-formed sheet of material, and the term “depositing” and its grammatical variants can refer to forming a component in situ, such as, for example, applying a liquid coating layer or otherwise forming a component using a chemical or physical deposition technique.

As used herein, the term “adjacent” describes the relative positioning of layers, coats, films, sheets, photovoltaic cells, and other components comprising a photovoltaic module, wherein the components can be either in direct physical contact or indirectly positioned beside another component with an intervening component or space. Accordingly, and by way of example, where a first component is said to be positioned adjacent to a second component, it is understood that the first component can be, but is not necessarily, in direct physical contact with the second component.

It is contemplated that one coat or component can be either directly positioned or indirectly positioned beside another adjacent component or coat. In the invention, where one component or coat is indirectly positioned beside another component or coat, it is contemplated that additional intervening layers, coats, photovoltaic cells, and the like can be positioned in between adjacent components. Accordingly, and by way of example, where a first coat can be said to be positioned adjacent to a second coat, it is contemplated that the first coat can be, but is not necessarily, directly beside and adhered to the second coat.

Similar elements of the photovoltaic module produced by method 300 comprise substantially similar materials and perform substantially similar functions as those corresponding elements described above in connection to the photovoltaic modules 100 and 200 shown respectively in FIGS. 1 and 2. For example, the photovoltaic cell, the front transparency, the encapsulating material, the treated surface, and the back coat of the photovoltaic module produced by method 300 can comprise the same materials and perform the same functions, respectively, as the photovoltaic cell 102, the front transparency 106, the encapsulating material 106, the treated surface 110 and the back coat 112 of the photovoltaic module 100 of FIG. 1. Similar to the encapsulant layer 106 of the photovoltaic module 100, the encapsulant layer of the photovoltaic module produced by method 300 can comprise a silicone encapsulant or a cured clear liquid encapsulant. The photovoltaic module produced by method 300 can comprise a photovoltaic cell comprising a crystalline silicon wafer. The photovoltaic module produced by method 300 can comprise a photovoltaic cell comprising a thin film photovoltaic cell.

Depositing the back coat (see step 320) can comprise spraying the liquid coating composition forming the back coat onto the surface of the treated encapsulating material opposite the front transparency. As described above in connection with the back coats 112 and 210, the back coat of the photovoltaic module produced by method 300 can be deposited onto all or a portion of the treated encapsulating material layered over the photovoltaic cell to form a coat or layer thereon (e.g., topcoat, primer coat, tie coat, clearcoat, or the like) using any suitable coating application technique, for example, by spraying, dipping, rolling, brushing, roller coating, curtain coating, flow coating, slot die coating, and the like, and combinations of any thereof.

Accordingly, the present disclosure relates in particular to the following non-limiting invention: In a first method, Method 1, the present disclosure provides a method for preparing a photovoltaic module comprising depositing an encapsulating material onto at least a portion of a photovoltaic cell, curing the encapsulating material, treating at least a portion of the cured encapsulating material, depositing a liquid coating composition onto at least a portion of the treated encapsulating material, and curing the liquid coating composition to form a back coat.

In another method, Method 2, the present disclosure provides a method for preparing a photovoltaic module as provided in Method 1, wherein the encapsulating material comprises a silicone encapsulant.

In another method, Method 3, the present disclosure provides a method for preparing a photovoltaic module as provided in Method 1 or Method 2, wherein treating comprises treating at least a portion of a surface of the cured the encapsulating material with a corona discharge, plasma, an ultraviolet ozone, a plume discharge, a brush discharge, a glow discharge, a luminous discharge, a texturing process, or combinations of any thereof.

In another method, Method 4, the present disclosure provides a method for preparing a photovoltaic module as provided in either Method 1-3, wherein treating comprises treating at least a portion of a surface of the cured encapsulating material that can be opposite to a front transparency with a corona discharge, a plasma, an ultraviolet ozone, a plume discharge, a brush discharge, a glow discharge, a luminous discharge, or combinations of any thereof.

In another method, Method 5, the present disclosure provides a method for preparing a photovoltaic module as provided in any of Methods 1-4, further comprising texturing at least a portion of a surface of the cured encapsulating material before or after treating the cured encapsulating material with a corona discharge, a plasma, and/or an ultraviolet ozone.

In another method, Method 6, the present disclosure provides a method for preparing a photovoltaic module as provided in any of Methods 1-5, wherein the liquid coating composition comprises a polyisocyanate, a polyamine, and a diamine chain extender.

In another method, Method 7, the present disclosure provides a method for preparing a photovoltaic module as provided in any of Methods 1-6, wherein the liquid coating composition further comprises an amine-functional silicone different from the polyamine and/or a hydroxy-functional silicone.

In another method, Method 8, the present disclosure provides a method for preparing a photovoltaic module as provided in any of Methods 1-7, wherein the liquid coating composition comprises a fluoropolymer resin or a polyurea resin.

In another method, Method 9, the present disclosure provides a method for preparing a photovoltaic module as provided in any of Methods 1-8, after treating the cured encapsulating material, further comprising depositing a primer onto at least a portion of the treated encapsulating material, curing the primer; and depositing a liquid coating composition onto at least a portion of the cured primer.

In another method, Method 10, the present disclosure provides a method for preparing a photovoltaic module as provided in any of Methods 1-9, wherein the primer comprises silicone.

In another method, Method 11, the present disclosure provides a method for preparing a photovoltaic module as provided in any of Methods 1-10, wherein the primer comprises octamethyltrisiloxane.

In another method, Method 12, the present disclosure provides a method for preparing a photovoltaic module as provided in any of Methods 1-11, wherein the photovoltaic cell comprises a crystalline silicon wafer.

In another method, Method 13, the present disclosure provides a method for preparing a photovoltaic module as provided in any of Methods 1-12, wherein the photovoltaic cell comprises a thin film photovoltaic cell directly adhered to a front transparency.

In another method, Method 14, the present disclosure provides a method for preparing a photovoltaic module as provided in any of Methods 1-13, wherein the encapsulating material comprises a flowable coating composition which can be cured to a clear layer after deposition.

In another method, Method 15, the present disclosure provides a method for preparing a photovoltaic module as provided in any of Methods 1-14, wherein the encapsulating material further comprises an adhesion promoting additive.

In another method, Method 16, the present disclosure provides a method for preparing a photovoltaic module as provided in any of Methods 1-15, wherein the encapsulating material comprises a silicone encapsulant and an additive comprising an isocyanate-functional silane, a hydroxy-functional silane, an amine-functional silane, or combinations of any thereof.

In another method, Method 17, the present disclosure provides a method for preparing a photovoltaic module comprising depositing a silicone encapsulant onto at least a portion of a photovoltaic cell, curing the silicone encapsulant; treating the cured silicone encapsulant with a corona discharge, a plasma, and/or an ultraviolet ozone, depositing a liquid coating composition onto at least a portion of the treated silicone encapsulant, wherein the liquid coating composition comprises a polyurea resin formed from a coating composition comprising a polyisocyanate, a polyamine having the structure:

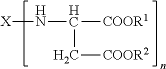

wherein n is an integer of 2 to 4, X represents an organic group which has a valency of n that is inert to isocyanate groups, and R1 and R2 represent organic groups that are inert to isocyanate groups, a diamine chain extender, and an amine-functional and/or hydroxy-functional silicone, and curing the liquid coating composition to form a back coat.

In a first photovoltaic module, Module 1, the present disclosure provides a photovoltaic module comprising a front transparency, a photovoltaic cell, an encapsulating material deposited on at least a portion of the photovoltaic cell, a treated surface of at least a portion of the encapsulating material, and a back coat deposited on at least a portion of the treated surface of the encapsulating material.

In another photovoltaic module, Module 2, the present disclosure provides a photovoltaic module as provided in Module 1, wherein the treated surface of the encapsulating material comprises a surface of a cured layer formed from a flowable coating composition, wherein at least a portion of the surface can be treated with a corona discharge, a plasma, an ultraviolet ozone, a plume discharge, a brush discharge, a glow discharge, a luminous discharge, or combinations of any thereof.

In another photovoltaic module, Module 3, the present disclosure provides a photovoltaic module as provided in either Module 1 or 2, wherein the back coat comprises a cured layer formed from a liquid coating composition comprising a polyisocyanate, a polyamine, and a diamine chain extender.

The invention is described and illustrated in this specification to provide an overall understanding of the structure, function, properties, and use of the disclosed modules and processes. It is understood that the invention described and illustrated in this specification is non-limiting and non-exhaustive. Thus, the present disclosure is not limited by the description of the invention as disclosed in this specification. The features and characteristics described in connection with examples of the invention can be combined with the features and characteristics of other examples of the invention. Such modifications and variations are intended to be included within the scope of this specification. As such, the claims can be amended to recite any features or characteristics expressly or inherently described in, or otherwise expressly or inherently supported by, this specification. Further, Applicants reserve the right to amend the claims to affirmatively disclaim features or characteristics that may be present in the prior art. Therefore, any such amendments comply with written description support requirements. The invention disclosed and described in this specification can comprise, consist of, or consist essentially of the features and characteristics as variously described herein.

In this specification, other than where otherwise indicated, all numerical parameters are to be understood as being prefaced and modified in all instances by the term “about”, in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described in this specification should at least be construed in light of the number of reported significant digits and by applying ordinary rounding techniques.

Also, any numerical range recited in this specification is intended to include all sub-ranges of the same numerical precision subsumed within the recited range. For example, a range of “1.0 to 10.0” is intended to include all sub-ranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited in this specification is intended to include all lower numerical limitations subsumed therein and any minimum numerical limitation recited in this specification is intended to include all higher numerical limitations subsumed therein. Accordingly, Applicants reserve the right to amend this specification, including the claims, to expressly recite any sub-range subsumed within the ranges expressly recited herein. All such ranges are intended to be inherently described in this specification such that amending to expressly recite any such sub-ranges would comply with written description support requirements.

The grammatical articles “one”, “a”, “an”, and “the”, as used in this specification, are intended to include “at least one” or “one or more”, unless otherwise indicated. Thus, the articles are used in this specification to refer to one or more than one (i.e., to “at least one”) of the grammatical objects of the article. By way of example, “a photovoltaic cell” means one or more photovoltaic cells, and thus, possibly, more than one photovoltaic cell can be contemplated and can be employed or used in an implementation of the described invention. Further, the use of a singular noun includes the plural, and the use of a plural noun includes the singular, unless the context of the usage requires otherwise.

Any patent, publication, or other disclosure material identified herein is incorporated by reference into this specification in its entirety unless otherwise indicated, but only to the extent that the incorporated material does not conflict with existing definitions, statements, or other disclosure material expressly set forth in this specification. As such, and to the extent necessary, the express disclosure as set forth in this specification supersedes any conflicting material incorporated by reference herein. Any material, or portion thereof, that is said to be incorporated by reference into this specification, but which conflicts with existing definitions, statements, or other disclosure material set forth herein, is only incorporated to the extent that no conflict arises between that incorporated material and the existing disclosure material. Applicant(s) reserve the right to amend this specification to expressly recite any subject matter, or portion thereof, incorporated by reference herein.

The non-limiting and non-exhaustive examples that follow are intended to further describe the invention without restricting the scope of the invention as described in this specification.

### EXAMPLES

### Example-1

Glass plates including a protective coating system comprising a surface treated encapsulant material and a cured back coat were evaluated. The glass plates comprising the protective coating system were compared to glass plates comprising an encapsulant material lacking any surface treatment of the encapsulant material before deposition of a protective coating.

Control and test glass plates were prepared using SOLARPHIRE® photovoltaic glass plates cleaned with a cleaning solution 1:1 ratio of deionized water to isopropanol. SOLARPHIRE® photovoltaic glass is commercially available from PPG Industries, Inc., Pittsburgh, Pa., USA. The glass plates were produced by spray coating onto the back side of each cleaned glass plate a liquid thermosetting silicone material (DOW CORNING® PV 6150, commercially available from Dow Corning Corporation, Midland, Mich., USA), covering the glass plate, and curing at 100° C. for 10 minutes to form a back side encapsulant layer.

A first control plate “A” was produced by spray coating a polyurea resin Formulation 1(see Table 1) directly onto the untreated cured silicone encapsulant material. The polyurea resin Formulation 1 was initially cured for 4to 10 hours at ambient temperature 77° F. (25° C.) and subsequently cured for 24 hours at 140° F. (60° C.) to form a back coat of the control plate A.

Test plate “B” was produced by spray coating a cured encapsulant material (as prepared and described in plate A) with DOW CORNING® 1200OS (an octamethyltrisiloxane based primer, commercially available from Dow Corning Corporation, Midland, Mich., USA), drying the primer at ambient temperature 77° F. (25° C.), and spray depositing the polyurea resin Formulation 1 coating directly onto the primer coated and cured silicone encapsulant material. Following deposition, the polyurea resin Formulation 1 was cured (as described above for control plate A) to form a back coat of the test plate B.

Test plate “C” was produced by treating the surface of a cured encapsulant material (as prepared and described in plate A) with a single pass of a hand held Corona discharge unit, a BD-20AC Laboratory Corona Treater, (commercially available from Electro-Technic Products, Chicago, Ill., USA) administered at a distance from the instrument to the surface in a range of ⅛ inch (0.32 cm) to 1inch (2.54 cm). The corona discharge treated surface of the encapsulant material was subsequently spray coated with the polyurea resin Formulation 1 directly onto the corona discharge treated and cured silicone encapsulant material. Following deposition, the polyurea resin Formulation 1 was cured (as described above for control plate A) to form a back coat of the test plate C.

A second control plate “D” was produced by spray coating a CORAFLON® fluoropolymer resin directly onto the untreated cured silicone encapsulant material. CORAFLON® is a fluoropolymer resin commercially available from PPG Industries, Inc., Pittsburgh, Pa., USA. The CORAFLON® fluoropolymer resin coating was initially cured for 4 to 10 hours at ambient temperature 77° F. (25° C.) and cured a second time at 140° F. (60° C.) for 24 hours to form a back coat of the control plate D.

Test plate “E” was produced by spray coating a cured encapsulant material (as prepared and described in plate D) with DOW CORNING® 1200OS (an octamethyltrisiloxane based primer), drying the primer at ambient temperature 77° F. (25° C.), before spray depositing a CORAFLON® fluoropolymer resin coating directly onto the primer coated and cured silicone encapsulant material. Following deposition, the CORAFLON® fluoropolymer resin coating was cured (as described above for control plate D) to form a back coat of the test plate E.

Test plate “F” was produced by treating a surface of a cured encapsulant material (as prepared and described for control plate D) with a single pass of a hand held Corona discharge unit (as described above for test plate C). The corona discharge treated surface of the encapsulant material was subsequently sprayed with a CORAFLON® fluoropolymer resin coating directly onto the corona discharge treated and cured silicone encapsulant material. The CORAFLON® fluoropolymer resin coating was subsequently cured to form a back coat of the test plate F using the curing conditions described above for CORAFLON® fluoropolymer resin (see control plate D).

The polyurea resin back coat Formulation 1 is provided in Table 1 (values in weight percentages unless otherwise indicated).

TABLE 1

| | Formulation 1 | Formulation 1 |
|---|---|---|
| Component | Part A | Part B |
| ¹ JEFFAMINE T5000 | 20 | |
| ²TEGO PROTECT 5000 | 4.2 | |
| ³ AEROSIL R805 | 1.5 | |
| ⁴ DESMOPHEN NH 1420 | 27 | |
| ⁵ HXA CE 425 | 42.1 | |
| ⁶DABCO T-12 | 0.5 | |
| ⁷JEFFLINK 754 | 6.1 | |
| ⁸ BYK-9077 | 0.5 | |
| ⁹TINUVIN 292 | 2 | |
| ¹⁰ BENTONE 34 | 34 | |
| ¹¹ TI-PURE R-900 | 5 | |
| Titanium Dioxide | | |
| ¹² PPG CAT 136 | | Mixing A/B = 1/1 |
| | | (volume ratio) |

¹ JEFFAMINET5000 is a trifunctional primary polyoxypropylenediamine of approximately 5000 molecular weight available from Huntsman Corporation, The Woodlands, TX, USA.
²TEGO PROTECT 5000 is a hydroxy-functional dimethyl siloxane available from Evonik Industries AG, Essen, Germany.
³ AEROSIL R805 is a fumed silica after treated with an octylsilane available from Evonik Industries AG, Essen, Germany.
⁴ DESMOPHEN NH 1420 is a polyaspartic ester available from Bayer Material Science LLC, Pittsburgh, PA, USA.
⁵ HXA CE 425 is an aliphatic diamine chain extender available from The Hanson Group, LLC, Alpharetta, GA, USA.
⁶DABCO T-12 is dibutyltin dilaurate, (DBTDL) available from Air Products and Chemicals, Inc., Allentown, PA, USA
⁷JEFFLINK 754 is a cycloaliphatic isophorone-based secondary diamine available from Huntsman Corporation, The Woodlands, TX, USA.
⁸ BYK-9077 is a wetting agent/dispersant available from Altanta AG, Wesel, Germany.
⁹TINUVIN 292 is a hindered amine. UV stabilizer available from BASF, Ludwigshafen, Germany.
¹⁰ BENTONE 34 is an organic derivative of bentonite clay rheological additive available from Elementis Specialties, Inc., Highstown, NJ, USA.
¹¹ TI-PURE R-900 Titanium Dioxide is a titanium dioxide pigment available from DuPont Titanium Technologies, USA.
¹² PPG CAT 136 is an aliphatic polyisocyanate available from PPG Industries, Inc., Pittsburgh, PA, USA. PPG CAT 136 (B) is mixed with the remaining ingredients (A) in Table 1 in a 1:1 volume ratio.

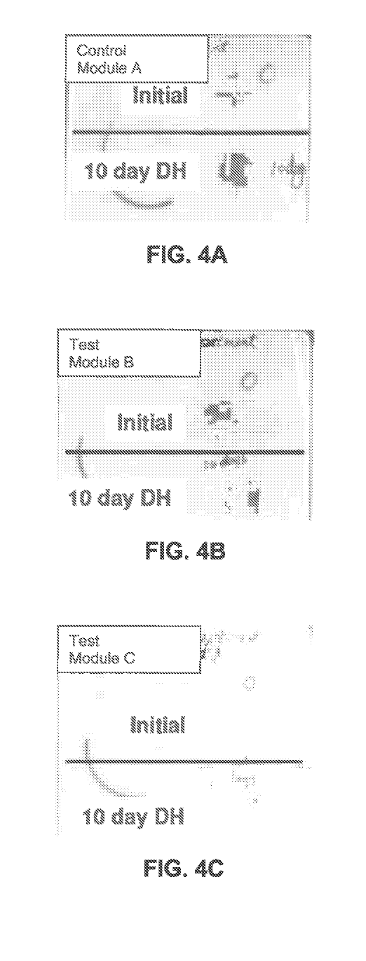

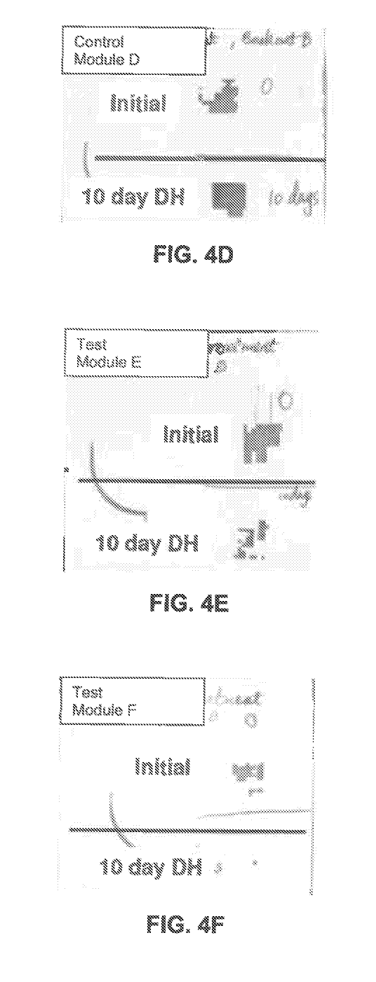

As shown in FIGS. 4A and 4B, the two control plates, A and D, and encapsulating material surface treated test plates B, C, E and F, were subjected to damp heat testing under IEC 61215:2005 Standard Test 10.13, conducted in accordance with IEC 60068-2-78 (85±2° C., 85±3% relative humidity). The control and surface treated test plates were tested for cross-hatch adhesion properties using Scotch High-Performance Masking Tape 232, commercially available from 3M Co., St. Paul, Minn., after 10 days of damp heat (DH) exposure. The results of the damp heat/cross-hatch adhesion testing are provided in Table 2.The color change data was determined using a Macbeth Color-Eye Spectrophotometer 2145, commercially available from X-Rite, Grand Rapids, Mich., USA. The value given for color change in Table 2 is the change in the spectrophotometric readings, or the value for “ΔE” following 10 days of damp heat exposure testing.

TABLE 2

| | | | | Color | Crosshatch Adhesion Results | |
|---|---|---|---|---|---|---|
| | | | | Change | | 10 days at |
| | | Back | | After 10 days | | 85° C. and |
| | Surface | Coat | Initial | Damp Heat | | 85% Relative |
| Plate | Treatment | Formula | Appearance | Exposure | Initial | Humidity |
| A | None | 1 | Good | 1.31 | 15-20% | >50% Peel off |
| | | | | | Peel off | from |
| | | | | | from | encapsulant |
| | | | | | encapsulant | material |
| | | | | | material | |
| B | DC1200 | 1 | Good | 1.69 | 20-30% | 10% |
| | OS | | | | Peel off | Adhesive |
| | | | | | from | failure + 10% |
| | | | | | encapsulant | Adhesive |
| | | | | | material | failure from |
| | | | | | | glass |
| C | Corona | 1 | Good | 1.34 | 1% | 1% Adhesive |
| | discharge | | | | Adhesive | failure |
| | | | | | failure | |
| D | None | CORA- | Delamination | 1.78 | >80% Peel | >70% Peel off |
| | | FLON ® | Bubbles | | off from | from |
| | | | | | encapsulant | encapsulant |
| | | | | | material | material |
| E | DC1200 | CORA- | 2-3 | 1.10 | >80% Peel | 25-30% Peel |
| | OS | FLON ® | Delamination | | off from | off from |
| | | | Spots | | encapsulant | encapsulant |
| | | | | | material | material |
| F | Corona | CORA- | Good | 1.45 | 20-30% | 1% Adhesive |
| | discharge | FLON ® | | | Adhesive | failure |
| | | | | | failure | |

FIGS. 4A through 4F show the observations and cross-hatch adhesion test results for the control and test plates before and after 10 days of damp heat exposure.

FIG. 4A shows a back side of a control plate A coated with a polyurea resin back coat after cross-hatch adhesion testing shown before and after 10 days of damp heat exposure. As shown in FIG. 4A, initial cross-hatch adhesion testing and visual inspection of the control plate A at time zero, before exposure to damp heat testing, showed a small amount of delamination to the polyurea resin Formulation 1 back coat. Following damp heat exposure for 10 days and cross-hatch adhesion testing, visual inspection showed a large amount of delamination and peeling of the polyurea resin Formulation 1 back coat from the encapsulating material.

FIG. 4B shows a back side of a test plate B coated with a DOW CORNING® 1200 OS primer and a polyurea resin backcoat after cross-hatch adhesion testing shown before and after 10 days of damp heat exposure. Initial cross-hatch adhesion testing and visual inspection of test plate B of FIG. 4B showed a moderate amount of delamination and peeling of the polyurea resin Formulation 1 back coat from the encapsulating material before damp heat exposure. Following damp heat exposure for 10 days, the primer treated test plate B also showed delamination and peeling of the polyurea resin Formulation 1 back coat from the encapsulating material.

FIG. 4C shows a back side of a test plate C treated with a corona discharge and a polyurea resin backcoat following cross-hatch adhesion testing shown before and after 10 days of damp heat exposure. In contrast to both the control plate A and the primer treated test plate B of FIGS. 4A and 4B, initial cross-hatch adhesion testing and visual inspection of the corona discharge treated test plate C showed only a single spot of peeling of the polyurea resin Formulation 1 back coat from the encapsulating material before damp heat exposure (see just above the horizontal line). The corona discharge treated test plate C also showed a single spot of peeling from the encapsulating material after the 10 day damp heat exposure.

FIG. 4D shows a back side of a control plate D coated with a CORAFLON® fluoropolymer resin back coat following cross-hatch adhesion testing shown before and after 10 days of damp heat exposure. As shown in FIG. 4D, an initial visual inspection of the control plate D at time zero, before exposure to damp heat testing, showed delamination and peeling of the CORAFLON® back coat from the encapsulating material. Following damp heat exposure for 10 days the control plate D showed increased delamination and peeling of the CORAFLON® back coat from the encapsulating material.

FIG. 4E shows a back side of a test plate E coated with a DOW CORNING® 1200 OS primer and a CORAFLON® fluoropolymer resin backcoat following cross-hatch adhesion testing shown before and after 10 days of damp heat exposure. Cross-hatch adhesion test results of test plate E before damp heat exposure showed both delamination and peeling of the CORAFLON® back coat from the encapsulating material. Following damp heat exposure for 10 days and cross-hatch adhesion testing, the primer treated test plate E also showed delamination and peeling of the CORAFLON® back coat from the encapsulating material.

FIG. 4F shows a back side of a test plate treated with a corona discharge and a CORAFLON® fluoropolymer resin backcoat after cross-hatch adhesion testing shown before and after 10 days of damp heat exposure. Similar to results shown in both the control plate D and the primer treated test plate E, the cross-hatch adhesion test results of the corona discharge treated test plate F showed delamination and peeling of the CORAFLON® back coat from the encapsulating material before damp heat exposure. However, the cross-hatch adhesion test results of the corona discharge treated test plate F showed only a single spot of peeling after the damp heat exposure.

In conclusion, the empirical results showed that the corona discharge surface treatment of the encapsulant material (see test plates C and F of FIGS. 4C and 4F, respectively) proved to be the most effective method for improving adhesion of the back coat to the encapsulant material, even following 10 days of damp heat exposure. The use of a primer coat between the encapsulating material and the back coat (see test plates B and E of FIGS. 4B and 4E, respectively) did not show significant improvement for adhesion of the back coat formulations. However, the primer coated surface treatment of the encapsulating material did improve the adhesion of the back coat formulations following damp heat exposure.

### Example-2

Samples comprising glass plates including a protective coating system comprising a surface treated and cured back side encapsulant and a cured back coat were evaluated for adhesion properties of the back coat to the encapsulant surface.

Test plates were prepared using SOLARPHIRE® photovoltaic glass plates cleaned with a cleaning solution 1:1 ratio of deionized water to isopropanol. Two test plates were produced by depositing a liquid thermosetting silicone coating encapsulant material (DOW CORNING® PV 6150) onto the back sides of glass test plates. A layer of mesh fabric with mesh size No. 80, commercially available from JoAnn Fabric and Craft Stores, Hudson, Ohio, USA, was placed adjacent to the freshly deposited liquid encapsulant material. The fabric covered encapsulant material was subsequently cured at 100° C. for 10 minutes to form a back side encapsulant layer. Following the curing process the mesh fabric was removed from the encapsulant material providing a mesh imprinted surface of the cured encapsulant material. The imprinted surface of the encapsulating material of a test plate “A” was spray coated with the polyurea resin Formulation 1 (see Table 2) onto the surface textured and cured silicone encapsulant layer. The deposited polyurea resin coating Formulation 1 was initially cured for 4 to 10 hours at ambient temperature 77° F. (25° C.) and subsequently cured for 24 hours at 140° F. (60° C.) to form a back coat.

A second test plate “B” was produced by spray coating a CORAFLON® fluoropolymer resin directly onto the surface imprinted and cured silicone encapsulant material. The CORAFLON® fluoropolymer resin coating was cured at ambient temperature 77° F. (25° C.) for 4-10 hours and cured again at 140° F. (60° C.) for 24 hours to form a back coat of the test plate B.

The test plates were evaluated by visual inspection for quality of adhesion of the cured back coat to the cured encapsulating material using a cross-hatch adhesion test with Scotch High-Performance Masking Tape 232, commercially available from 3M Corporation, St. Paul, Minn., USA. Upon visual inspection, test plate A showed adhesive failure between the surface imprinted encapsulant material and the polyurea resin Formulation 1 back coat. In contrast, upon visual inspection, test plate B showed less than 20% delamination and peeling of the CORAFLON® fluoropolymer resin back coat from the surface textured encapsulating material.

In conclusion, the empirical results showed that the CORAFLON® fluoropolymer resin back coat of test plate B provided improved adhesion to the surface textured and cured silicone encapsulating material as compared to the polyurea resin of Formulation 1.

### Example 3

Samples comprising glass plates including a protective coating system comprising a cured back side encapsulant (non-treated surface) and a cured back coat were evaluated for adhesion properties of the back coat to the encapsulant surface.

Test plates were prepared using SOLARPHIRE® photovoltaic glass plates cleaned with a cleaning solution 1:1 ratio of deionized water to isopropanol. Test plates were produced by depositing a liquid thermosetting silicone coating encapsulant material (DOW CORNING® PV 6150) onto the back sides of the cleaned test plates. The encapsulant material was subsequently cured at 100° C. for 10 minutes to form a back side encapsulant layer. The test plates were spray coated with a CORAFLON® fluoropolymer resin directly onto the (non-treated) surface of the cured silicone encapsulant material. The CORAFLON® fluoropolymer resin coating was initially cured at ambient temperature (77° F., 25° C.) for 4 to 10 hours and then at 140° F. (60° C.) for 24 hours to form a back coat of the test plate.

The test plates were subjected to damp heat testing under IEC 61215:2005 Standard Test 10.13, conducted in accordance with IEC 60068-2-78 (85±2° C., 85±3% relative humidity). The damp heat test plates were tested for cross-hatch adhesion properties using Scotch High-Performance Masking Tape 232, commercially available from 3M Co., St. Paul, Minn., after 500 hours of damp heat (DH) exposure.

The test plates were evaluated by visual inspection for quality of adhesion of the cured back coat to the cured encapsulating material. Visual inspection of the test plates after 500 hours of damp heat exposure showed no delamination of the CORAFLON® fluoropolymer resin back coat from the encapsulating material. However, cross-hatch adhesion test results of the test plates as evaluated before and after 500 hours of damp heat exposure both showed adhesive failure between the CORAFLON® fluoropolymer resin back coat and the encapsulating material.

In conclusion, the empirical results showed that the CORAFLON® fluoropolymer resin back coat adhesion to the untreated surface of the encapsulating material survived the curing process for visual inspection. However, the observed adhesive property was not sufficient to survive cross-hatch adhesion testing. Further, no improvement was observed in the adhesion of the CORAFLON® fluoropolymer resin back coat to the untreated surface of the encapsulating material after 500 hours of damp heat exposure and cross-hatch adhesion testing.

### Example 4

Glass plates including a protective coating system comprising a cured back side encapsulant (non-treated surface) and a cured back coat were evaluated for adhesion properties of the back coat to the encapsulant surface

Test plates were prepared using SOLARPHIRE® photovoltaic glass plates cleaned with a cleaning solution 1:1 ratio of deionized water to isopropanol. SOLARPHIRE® photovoltaic glass is commercially available from PPG Industries, Inc., Pittsburgh, Pa., USA. Two test plates were produced by depositing a liquid thermosetting silicone coating encapsulant material (DOW CORNING® PV 6150) onto each of the back sides of the cleaned glass test plates and curing at 100° C. for 10 minutes to form a back side encapsulant layer. Each test plate was subsequently spray coated with either polyurea resin Formulation 1 (see Table 1) or CORAFLON® fluoropolymer resin and cured (as previously described) to form the back coats of the test plates.

The polyurea resin Formulation 1 was initially cured for 4 to 10 hours at ambient temperature 77° F. (25° C.) and subsequently cured for 24 hours at 140° F. (60° C.) to form a back coat of a first test plate. The CORAFLON® fluoropolymer resin coating was cured at ambient temperature 77° F. (25° C.) for 4-10 hours and cured again at 140° F. (60° C.) for 24 hours to form a back coat of a second test plate.

Visual inspection of the test plates during the post curing process at 140° F. (60° C.) showed delamination bubbling of the polyurea resin back coats of both test plates. In each case, the delamination and adhesive failure was found between the polyurea resin back coats Formulations 3 and 4, and the untreated surface of the cured encapsulant material.

In conclusion, the empirical results showed that the adhesion of the polyurea resin back coats (i.e., Formulations 3 and 4) and the untreated surface of the encapsulant material was insufficient to endure the curing process.

### Example 5

Glass plates including a protective coating system comprising a cured back side encapsulant (non-treated surface) and a cured back coat were evaluated for adhesion properties of the back coat to the encapsulant surface.

Test plates were evaluated for adhesion properties between an encapsulating material and a cured polyurea resin back coat. Test plates were prepared using SOLARPHIRE® photovoltaic glass plates cleaned with a cleaning solution 1:1 ratio of deionized water to isopropanol. The cleaned test plates were coated by depositing a liquid thermosetting silicone coating encapsulant material (DOW CORNING® PV 6150) onto each of the back sides of glass test plates. The coated test plates were cured at 100° C. for 10 minutes to form a back side encapsulant layer. Each test plate was subsequently spray coated with a polyurea resin coating code Q900GY481, commercially available from PPG Industries, Inc., Pittsburgh, Pa., USA. The polyurea resin coating code Q900GY481 was cured at 140° F. (60° C.) for 30 minutes.

Visual inspection of the test plates during the spray coating process of the polyurea resin coating code Q900GY481 back coating showed failure to provide adhesion to the surface of the encapsulant material sufficient to cover the surface of the encapsulant material with the polyurea resin coating code Q900GY481 back coating.

In conclusion, the empirical results showed that the encapsulant material (absent a surface treatment) yielded a surface in which interfacial tension between the encapsulant material and the polyurea resin formula was high enough to prevent surface wettability and subsequent adhesion of the polyurea resin coating code Q900GY481, back coat to the encapsulant material surface.

Whereas it is understood, therefore, that this description is not limited to the invention disclosed, but is intended to cover modifications which are within the spirit and scope of the invention, as defined by the appended claims. This specification has been written with reference to the methods and photovoltaic modules of the invention. However, it will be recognized by persons having ordinary skill in the art that various substitutions, modifications, or combinations of any part of the disclosed invention (or portions thereof) can be made within the scope of this specification. Thus, it is contemplated and understood that this specification supports additional methods and photovoltaic modules not expressly set forth herein. Such inventions can be obtained, for example, by combining, modifying, or reorganizing any of the disclosed steps, step sequences, components, elements, features, characteristics, limitations, and the like, of the invention described in this specification. In this manner, Applicant(s) reserve the right to amend the claims during prosecution to add features as variously described in this specification, and such amendments comply with written description support requirements.

What is claimed is:

1. A method for preparing a photovoltaic module comprising:
depositing an encapsulating material onto at least a portion of a photovoltaic cell;
curing the encapsulating material;
treating at least a portion of a surface of the cured encapsulating material;
depositing a liquid coating composition onto at least a portion of the treated encapsulating material; and
curing the liquid coating composition to form a back coat.

2. The method of claim 1, wherein the encapsulating material comprises a silicone encapsulant.

3. The method of claim 1, wherein treating comprises treating at least a portion of a surface of the cured encapsulating material with a corona discharge, a plasma, an ultraviolet ozone, a plume discharge, a brush discharge, a glow discharge, a luminous discharge, a texturing process, or combinations of any thereof.

4. The method of claim 1, wherein treating comprises treating at least a portion of a surface of the cured encapsulating material that is opposite to a front transparency with a corona discharge, a plasma, an ultraviolet ozone, a plume discharge, a brush discharge, a glow discharge, a luminous discharge, or combinations of any thereof.

5. The method of claim 1, further comprising texturing at least a portion of a surface of the cured encapsulating material before or after treating the cured encapsulating material with a corona discharge, a plasma, and/or an ultraviolet ozone.

6. The method of claim 1, wherein the liquid coating composition comprises:
a polyisocyanate;
a polyamine; and
a diamine chain extender.

7. The method of claim 6, wherein the liquid coating composition further comprises an amine-functional silicone different from the polyamine and/or a hydroxy-functional silicone.

8. The method of claim 1, wherein the liquid coating composition comprises a fluoropolymer resin or a polyurea resin.

9. The method of claim 1, after treating the cured encapsulating material, further comprising:
depositing a primer onto at least a portion of the treated encapsulating material;
curing the primer; and
depositing a liquid coating composition onto at least a portion of the cured primer.

10. The method of claim 9, wherein the primer comprises a silicone.

11. The method of claim 9, wherein the primer comprises octamethyltrisiloxane.

12. The method of claim 1, wherein the photovoltaic cell comprises a crystalline silicon wafer.

13. The method of claim 1, wherein the photovoltaic cell comprises a thin film photovoltaic cell directly adhered to a front transparency.

14. The method of claim 1, wherein the encapsulating material comprises a flowable coating composition which is cured to a clear layer after deposition.

15. The method of claim 1, wherein the encapsulating material further comprises an adhesion promoting additive.

16. The method of claim 1, wherein the encapsulating material comprises a silicone encapsulant and an additive comprising an isocyanate-functional silane, a hydroxy-functional silane, an amine-functional silane, or combinations of any thereof.

17. A method for preparing a photovoltaic module comprising:
depositing a silicone encapsulant onto at least a portion of a photovoltaic cell;
curing the silicone encapsulant;
treating at least a portion of the cured silicone encapsulant with a corona discharge, a plasma, and/or an ultraviolet ozone;
depositing a liquid coating composition onto at least a portion of the treated silicone encapsulant,
wherein the liquid coating composition comprises a polyurea resin formed from a coating composition comprising:
a polyisocyanate;
a polyamine having the structure: 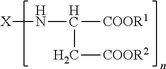
wherein:
n is an integer of 2 to 4
X represents an organic group which has a valency of n that is inert to isocyanate groups; and
R¹ and R² represent organic groups that are inert to isocyanate groups;
a diamine chain extender; and
an amine-functional and/or hydroxy-functional silicone; and curing the liquid coating composition to form a back coat.

18. A photovoltaic module comprising:
a front transparency;
a photovoltaic cell;
an encapsulating material deposited on at least a portion of the photovoltaic cell;
a treated surface of at least a portion of the encapsulating material; and
a back coat deposited on at least a portion of the treated surface of the encapsulating material.

19. The photovoltaic module of claim 18, wherein the treated surface of the encapsulating material comprises a surface of a cured layer formed from a flowable coating composition, wherein at least a portion of the surface can be treated with a corona discharge, a plasma, an ultraviolet ozone, a plume discharge, a brush discharge, a glow discharge, a luminous discharge, or combinations of any thereof.

20. The photovoltaic module of claim 18, wherein the back coat comprises a cured layer formed from a liquid coating composition comprising:
a polyisocyanate;
a polyamine; and
a diamine chain extender.
